(19) United States
(12) Patent Application Publication
(10) Pub. No.: US 2026/0331064 A1
(43) Pub. Date: Oct. 22, 2026

(54) DISPLAY PANEL AND DISPLAY DEVICE

(71) Applicant: Xiamen Tianma Display Technology Co., Ltd., Xiamen (CN)

(72) Inventors: Xuehuan FENG, Xiamen (CN); Yana GAO, Xiamen (CN); Xingyao ZHOU, Xiamen (CN); Zhiqiang XIA, Xiamen (CN); Kang YANG, Xiamen (CN); Lei WANG, Xiamen (CN)

(73) Assignee: Xiamen Tianma Display Technology Co., Ltd., Xiamen (CN)

(21) Appl. No.: 19/704,827

(22) Filed: Jun. 11, 2026

(30) Foreign Application Priority Data
Jan. 29, 2026 (CN) 202610128960.9

(51) Int. Cl. G09G 3/3266; G09G 3/20; G09G 3/3233; G11C 19/28

(52) U.S. Cl. CPC G09G 3/3266; G09G 3/3233; G11C 19/28; G09G 3/2007; G09G 2300/0842; G09G 2300/0861; G09G 2310/0286; G09G 2310/08; G09G 2320/0257; G09G 2340/0435

(57) ABSTRACT

Provided are a display panel and a display device. The display panel includes a driving circuit. The driving circuit includes multiple shift registers. A shift register includes a first control circuit, a second control circuit, an isolation control circuit, an output circuit, a signal input terminal, a first clock terminal, a second clock terminal, a first level terminal, a second level terminal, an isolation control terminal, and a signal output terminal. In the same shift register, during at least part of a period in which a signal at the second node is at an active level and an input signal at the signal input terminal is at an inactive level, a first clock signal at the first clock terminal controls the first control circuit to disconnect a signal transmission path between the signal input terminal and the first node.

### CROSS-REFERENCE TO RELATED APPLICATION

This application claims priority to Chinese Patent Application No. 202610128960.9 filed Jan. 29, 2026, the disclosure of which is incorporated herein by reference in its entirety.

### TECHNICAL FIELD

The present disclosure relates to the field of display technology, and in particular, to a display panel and a display device.

### BACKGROUND

With the development of display technology, electronic products with display functions are widely used in various fields. For example, televisions, mobile phones, computers, and personal digital assistants are all electronic products with display functions and have become an indispensable part of people's life and work. Among them, a display panel is a core structure for achieving the display function in an electronic product.

A pixel array and a driving circuit for driving the pixel array are generally disposed in the display panel. The driving circuit can perform row-by-row scanning on the pixel array to enable the pixel array to display images. However, limited by process fluctuations or equipment errors in fabricating the driving circuit, leakage current is generated inside the driving circuit, which causes problems such as display abnormality.

### SUMMARY

The present disclosure provides a display panel and a display device to provide a shift register circuit that can stably output driving signals, thereby improving the display effect and reliability of the product.

In a first aspect, the present disclosure provides a display panel that includes a driving circuit. The driving circuit includes multiple shift registers.

A shift register includes a first control circuit, a second control circuit, an isolation control circuit, an output circuit, a signal input terminal, a first clock terminal, a second clock terminal, a first level terminal, a second level terminal, an isolation control terminal, and a signal output terminal. The first control circuit is electrically connected to the signal input terminal, the first clock terminal, and a first node separately. The isolation control circuit is electrically connected to the isolation control terminal, the first node, and a second node separately. The second control circuit is electrically connected to the first clock terminal, the first level terminal, and a third node separately. The output circuit is electrically connected to the second node, the third node, the second clock terminal, the second level terminal, and the signal output terminal separately.

In the same shift register, during at least part of a period in which a signal at the second node is at an active level and an input signal at the signal input terminal is at an inactive level, a first clock signal at the first clock terminal controls the first control circuit to disconnect a signal transmission path between the signal input terminal and the first node, and/or an isolation control signal at the isolation control terminal controls the isolation control circuit to disconnect a signal transmission path between the first node and the second node.

In a second aspect, the present disclosure provides a display device that includes the display panel according to the first aspect.

### BRIEF DESCRIPTION OF DRAWINGS

FIG. 1 is a schematic diagram illustrating the circuit structure of a shift register in the related art.

FIG. 2 is a timing graph of the shift register in FIG. 1.

FIG. 3 is a top view of the structure of a display panel according to an embodiment of the present disclosure.

FIG. 4 is a first schematic diagram illustrating the circuit structure of a shift register according to an embodiment of the present disclosure.

FIG. 5 is a first timing graph of a shift register according to an embodiment of the present disclosure.

FIG. 6 is a second timing graph of a shift register according to an embodiment of the present disclosure.

FIG. 7 is a third timing graph of a shift register according to an embodiment of the present disclosure.

FIG. 8 is a second schematic diagram illustrating the circuit structure of a shift register according to an embodiment of the present disclosure.

FIG. 9 is a third schematic diagram illustrating the circuit structure of a shift register according to an embodiment of the present disclosure.

FIG. 10 is a fourth schematic diagram illustrating the circuit structure of a shift register according to an embodiment of the present disclosure.

FIG. 11 is a fourth timing graph of a shift register according to an embodiment of the present disclosure.

FIG. 12 is a fifth timing graph of a shift register according to an embodiment of the present disclosure.

FIG. 13 is a fifth schematic diagram illustrating the circuit structure of a shift register according to an embodiment of the present disclosure.

FIG. 14 is a sixth schematic diagram illustrating the circuit structure of a shift register according to an embodiment of the present disclosure.

FIG. 15 is a sixth timing graph of a shift register according to an embodiment of the present disclosure.

FIG. 16 is a seventh schematic diagram illustrating the circuit structure of a shift register according to an embodiment of the present disclosure.

FIG. 17 is a seventh timing graph of a shift register according to an embodiment of the present disclosure.

FIG. 18 is an eighth schematic diagram illustrating the circuit structure of a shift register according to an embodiment of the present disclosure.

FIG. 19 is a ninth schematic diagram illustrating the circuit structure of a shift register according to an embodiment of the present disclosure.

FIG. 20 is an eighth timing graph of a shift register according to an embodiment of the present disclosure.

FIG. 21 is a tenth schematic diagram illustrating the circuit structure of a shift register according to an embodiment of the present disclosure.

FIG. 22 is an eleventh schematic diagram illustrating the circuit structure of a shift register according to an embodiment of the present disclosure.

FIG. 23 is a twelfth schematic diagram illustrating the circuit structure of a shift register according to an embodiment of the present disclosure.

FIG. 24 is a thirteenth schematic diagram illustrating the circuit structure of a shift register according to an embodiment of the present disclosure.

FIG. 25 is a fourteenth schematic diagram illustrating the circuit structure of a shift register according to an embodiment of the present disclosure.

FIG. 26 is a fifteenth schematic diagram illustrating the circuit structure of a shift register according to an embodiment of the present disclosure.

FIG. 27 is a sixteenth schematic diagram illustrating the circuit structure of a shift register according to an embodiment of the present disclosure.

FIG. 28 is a seventeenth schematic diagram illustrating the circuit structure of a shift register according to an embodiment of the present disclosure.

FIG. 29 is an eighteenth schematic diagram illustrating the circuit structure of a shift register according to an embodiment of the present disclosure.

FIG. 30 is a ninth timing graph of a shift register according to an embodiment of the present disclosure.

FIG. 31 is a nineteenth schematic diagram illustrating the circuit structure of a shift register according to an embodiment of the present disclosure.

FIG. 32 is a twentieth schematic diagram illustrating the circuit structure of a shift register according to an embodiment of the present disclosure.

FIG. 33 is a twenty-first schematic diagram illustrating the circuit structure of a shift register according to an embodiment of the present disclosure.

FIG. 34 is a twenty-second schematic diagram illustrating the circuit structure of a shift register according to an embodiment of the present disclosure.

FIG. 35 is a twenty-third schematic diagram illustrating the circuit structure of a shift register according to an embodiment of the present disclosure.

FIG. 36 is a twenty-fourth schematic diagram illustrating the circuit structure of a shift register according to an embodiment of the present disclosure.

FIG. 37 is a twenty-fifth schematic diagram illustrating the circuit structure of a shift register according to an embodiment of the present disclosure.

FIG. 38 is a twenty-sixth schematic diagram illustrating the circuit structure of a shift register according to an embodiment of the present disclosure.

FIG. 39 is a twenty-seventh schematic diagram illustrating the circuit structure of a shift register according to an embodiment of the present disclosure.

FIG. 40 is a schematic diagram illustrating the structure of a pixel circuit according to an embodiment of the present disclosure.

FIG. 41 is a timing graph of the pixel circuit shown in FIG. 40 according to an embodiment of the present disclosure.

FIG. 42 is a diagram illustrating the structure of a display device according to an embodiment of the present disclosure.

### DETAILED DESCRIPTION

Hereinafter, the present disclosure is further described in detail in conjunction with the drawings and embodiments. It is to be understood that the embodiments described herein are only intended to illustrate but not to limit the present disclosure. Additionally, it is to be noted that for ease of description, only part, not all, of the structures related to the present disclosure are illustrated in the drawings.

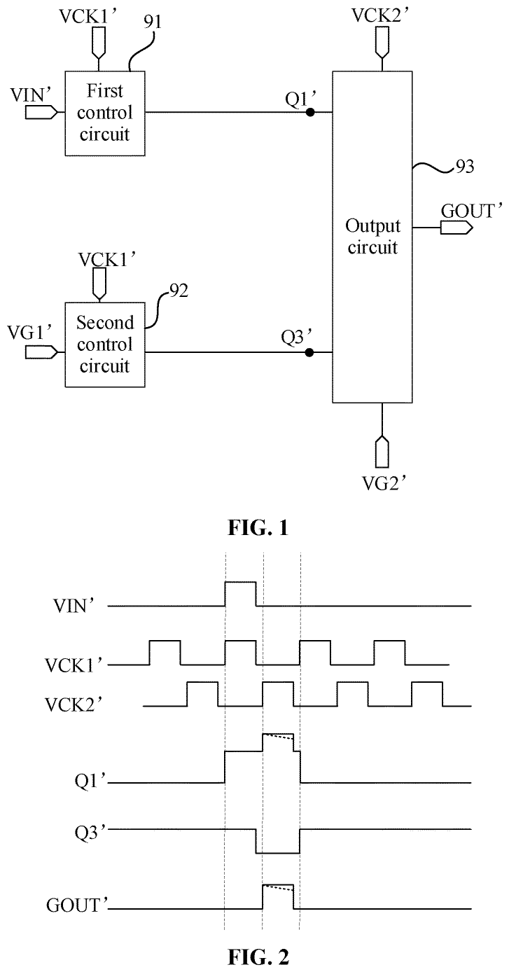

FIG. 1 is a schematic diagram illustrating the circuit structure of a shift register in the related art. With reference to FIG. 1, the shift register includes a first control circuit 91, a second control circuit 92, and an output circuit 93. The first control circuit 91 is electrically connected to a signal input terminal VIN′, a first clock terminal VCK1′, and a first node Q1′ separately. The first control circuit 91 may control a signal at the first node Q1′ according to an input signal from the signal input terminal VIN′ and a first clock signal from the first clock terminal VCK1′. The second control circuit 92 is electrically connected to a first level terminal VG1′, the first clock terminal VCK1′, and a third node Q3′ separately. The second control circuit 92 may control a signal at the third node Q3′ according to a first level signal from the first level terminal VG1′ and the first clock signal from the first clock terminal VCK1′. The output circuit 93 is electrically connected to the first node Q1′, the third node Q3′, a second clock terminal VCK2′, a second level terminal VG2′, and a signal output terminal GOUT′ separately. When the first node Q1′ is at an active level, the output circuit 93 may transmit a second clock signal from the second clock terminal VCK2′ to the signal output terminal GOUT'. The output circuit 93 may also transmit a second level signal from the second level terminal VG2′ to the signal output terminal GOUT′ when the third node Q3′ is at an active level. The potential at the second level terminal VG2′ is an inactive level of the signal output terminal OUT′.

FIG. 2 is a timing graph of the shift register in FIG. 1. An example in which the active level is a logic high level and the inactive level is a logic low level is used, and FIG. 2 illustrates potential changes at various nodes. With reference to FIG. 2, during a period in which the first node Q1′ is at a logic high level, the output circuit 93 can transmit the second clock signal from the second clock terminal VCK2′ to the signal output terminal GOUT′. When the second clock signal is at a logic high level, the signal output terminal GOUT′ can output a high-level signal. During a period in which the third node Q3′ is at a logic high level, the output circuit 93 can transmit a low-level signal from the second level terminal VG2′ to the output terminal OUT′, and the signal output terminal GOUT′ outputs a low-level signal.

Due to process errors, the threshold voltage of transistors in the shift register may be affected. When the absolute value of the threshold voltage is relatively small, a leakage path is formed. During a period in which the first node Q1′ is at an active level, the first node Q1′ leaks current to the first control circuit 91, causing the first node Q1′ to change from the active level to an inactive level (dashed line in FIG. 2). The potential change at the first node Q1′ affects the ability of the output circuit 93 to transmit the second clock signal from the second clock terminal VCK2′ to the signal output terminal GOUT′, thereby affecting the stability of the active level at the signal output terminal GOUT′. This causes distortion of the gate driving signal output by the shift register, affects the operation of the pixel circuit, and results in at least part of the display area being unable to display stably and accurately, thereby leading to a poor display effect.

To solve the above problem, an embodiment of the present disclosure provides a display panel. The display panel includes a driving circuit. The driving circuit includes multiple shift registers. A shift register includes a first control circuit, a second control circuit, an isolation control circuit, an output circuit, a signal input terminal, a first clock terminal, a second clock terminal, a first level terminal, a second level terminal, an isolation control terminal, and a signal output terminal. The first control circuit is electrically connected to the signal input terminal, the first clock terminal, and a first node separately. The isolation control circuit is electrically connected to the isolation control terminal, the first node, and a second node separately. The second control circuit is electrically connected to the first clock terminal, the first level terminal, and a third node separately. The output circuit is electrically connected to the second node, the third node, the second clock terminal, the second level terminal, and the signal output terminal separately. In the same shift register, during at least part of a period in which a signal at the second node is at an active level and an input signal at the signal input terminal is at an inactive level, a first clock signal at the first clock terminal controls the first control circuit to disconnect a signal transmission path between the signal input terminal and the first node, and/or an isolation control signal at the isolation control terminal controls the isolation control circuit to disconnect a signal transmission path between the first node and the second node.

Adopting the preceding technical solution, a driving circuit including multiple shift registers is disposed in the display panel so that an output circuit of each shift register can sequentially output an active pulse of a gate driving signal when a second node inside the shift register is at an active level, thereby ensuring the orderly operation of pixel circuits and enabling the display panel to display images. In addition, a first control circuit is disposed between the signal input terminal and the first node of the shift register, and an isolation control circuit is disposed between the first node and the second node. During at least part of a period in which the signal at the second node is at an active level and the input signal at the signal input terminal is at an inactive level, the first clock signal at the first clock terminal controls the first control circuit to disconnect the signal transmission path between the signal input terminal and the first node, and/or the isolation control signal at the isolation control terminal controls the isolation control circuit to disconnect the signal transmission path between the first node and the second node. This configuration cuts off the signal transmission path between the second node and the signal input terminal so that the signal at the second node can be maintained at the active level. This contributes to improving the stability of the signal at the second node, enabling the signal at the second node to control the signal output terminal of the output circuit to output a stable gate driving signal, and thereby improving the accuracy of the gate driving signal output by the shift register. Furthermore, when the gate driving signals output by the shift registers are used to perform row-by-row scanning on the pixel circuits in the display panel, each pixel circuit can receive an accurate gate driving signal. This contributes to improving the accuracy of light emission of the pixels, thereby improving the display effect of the display panel.

The above is the core idea of the present disclosure. Based on the embodiments of the present disclosure, all other embodiments acquired by those of ordinary skill in the art are within the scope of the present disclosure on the premise that no creative work is done. Technical solutions in the embodiments of the present disclosure are described clearly and completely hereinafter in conjunction with the drawings in the embodiments of the present disclosure.

It is to be noted that embodiments of the present disclosure, if not in collision, may be combined with each other.

FIG. 3 is a top view of the structure of a display panel according to an embodiment of the present disclosure. As shown in FIG. 3, a display panel 100 includes a driving circuit 10 located in a non-display area NA. The driving circuit 10 includes multiple shift registers 101. Illustratively, the display panel 100 also includes multiple pixel circuits 50 arranged in an array in a display area AA, and the pixel circuits 50 are arranged in pixel circuit rows in a horizontal direction. Multiple cascaded shift registers 101 are provided corresponding to the pixel circuit rows, respectively. A signal output terminal GOUT of a shift register 101 is connected to each pixel circuit 50 in a pixel circuit row through a scanning line 51. The pixel circuit 50 includes a light-emitting element and at least one transistor. The shift register 101 can output an active level to drive the pixel circuit 50.

It is to be noted that the drawing only illustratively shows that the shift register 101 is located on one side of the display area AA. In other embodiments, shift registers 101 may be located on two sides or three sides of the display area AA, or the shift register 101 may also be located in the display area AA. The specific arrangement position of the shift register 101 is not limited in the embodiment of the present disclosure.

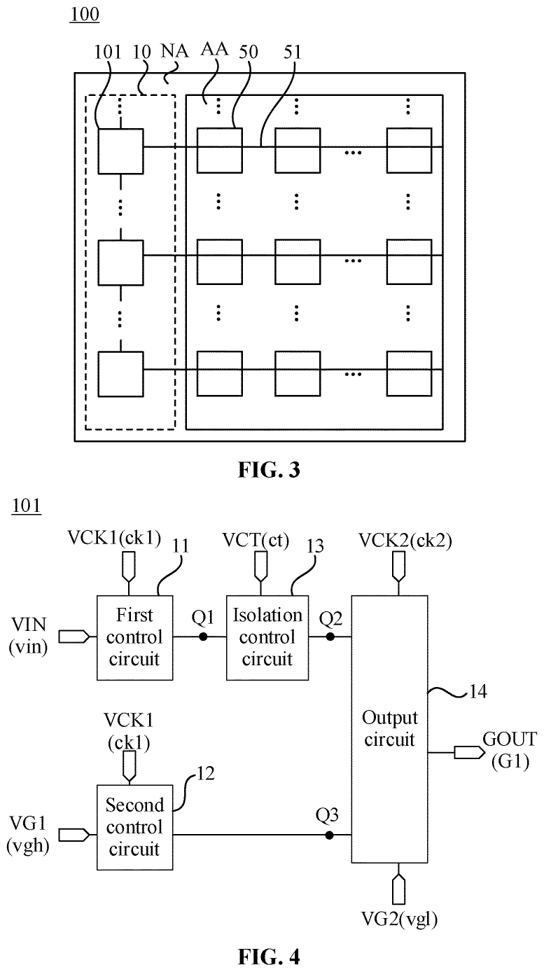

FIG. 4 is a first schematic diagram illustrating the circuit structure of a shift register according to an embodiment of the present disclosure. With reference to FIG. 3 and FIG. 4, the shift register 101 includes a first control circuit 11, a second control circuit 12, an isolation control circuit 13, an output circuit 14, a signal input terminal VIN, a first clock terminal VCK1, a second clock terminal VCK2, a first level terminal VG1, a second level terminal VG2, an isolation control terminal VCT, and a signal output terminal GOUT. The first control circuit 11 is electrically connected to the signal input terminal VIN, the first clock terminal VCK1, and a first node Q1 separately. The isolation control circuit 13 is electrically connected to the isolation control terminal VCT, the first node Q1, and a second node Q2 separately. The second control circuit 12 is electrically connected to the first clock terminal VCK1, the first level terminal VG1, and a third node Q3 separately. The output circuit 14 is electrically connected to the second node Q2, the third node Q3, the second clock terminal VCK2, the second level terminal VG2, and the signal output terminal GOUT separately.

The first level terminal VG1 may receive a first level signal. The second level terminal VG2 may receive a second level signal. In an embodiment, both the first level signal and the second level signal may be fixed levels, and the polarities of the first level signal and the second level signal may be opposite. That is, when the first level signal is a logic low-level signal vgl, the second level signal is a logic high-level signal vgh; or, when the first level signal is a logic high-level signal vgh, the second level signal may be a logic low-level signal vgl. The signal input terminal VIN may receive an input signal vin. The first clock terminal VCK1 may receive a first clock signal ck1. The second clock terminal VCK2 may receive a second clock signal ck2. The isolation control terminal VCT may receive an isolation control signal ct. The input signal vin, the first clock signal ck1, the second clock signal ck2, and the isolation control signal ct may all be non-fixed signals including a high-level signal and a low-level signal, and the logic high level and the logic low level of the first clock signal ck1 and the second clock signal ck2 may alternately change with a certain clock period.

Specifically, in the same shift register 101, the first control circuit 11 is electrically connected to the signal input terminal VIN, the first clock terminal VCK1, and the first node Q1 separately so that the first control circuit 11 can control a signal output from the first node Q1 according to the first clock signal ck1 at the first clock terminal VCK1 and the input signal vin at the signal input terminal VIN. The first control circuit 11 may establish or disconnect a signal transmission path between the signal input terminal VIN and the first node Q1 under the control of the first clock signal ck1 at the first clock terminal VCK1. Illustratively, when the first clock signal ck1 is at an active level, the first control circuit 11 may transmit the input signal vin from the signal input terminal VIN to the first node Q1 so that the signal at the first node Q1 can be consistent with the input signal vin.

The isolation control circuit 13 is electrically connected to the first node Q1, the second node Q2, and the isolation control terminal VCT separately so that the isolation control circuit 13 can control a signal at the second node Q2 according to the isolation control signal ct at the isolation control terminal VCT and the signal at the first node Q1, or control a signal at the first node Q1 according to the isolation control signal ct at the isolation control terminal VCT and the signal at the second node Q2. The isolation control circuit 13 may establish or disconnect a signal transmission path between the first node Q1 and the second node Q2 under the control of the isolation control signal ct at the isolation control terminal VCT. Illustratively, when the isolation control signal ct at the isolation control terminal VCT is at an active level, the isolation control circuit 13 may transmit the signal at the first node Q1 to the second node Q2, or transmit the signal at the second node Q2 to the first node Q1 so that the signal at the first node Q1 is consistent with the signal at the second node Q2. At the same time, the signal at the first node Q1 can be consistent with the input signal vin at the signal input terminal VIN. In this manner, the signal at the second node Q2 can be consistent with the input signal vin at the input terminal VIN. That is, during part of a period, the input signal vin at the signal input terminal VIN can be transmitted to the second node Q2 through the first control circuit 11 and the isolation control circuit 13.

The second control circuit 12 is electrically connected to the first level terminal VG1, the first clock terminal VCK1, and the third node Q3 separately so that the second control circuit 12 can control a signal output from the third node Q3 according to the first clock signal ck1 at the first clock terminal VCK1 and the first level signal at the first level terminal VG1. The second control circuit 12 may establish or disconnect a signal transmission path between the first level terminal VG1 and the third node Q3 under the control of the first clock signal ck1 at the first clock terminal VCK1. Illustratively, when the first clock signal ck1 is at an active level, the second control circuit 12 may transmit the first level signal from the first level terminal VG1 to the third node Q3 so that the signal at the third node Q3 can be consistent with the first level signal.

The output circuit 14 is electrically connected to the second clock terminal VCK2, the second node Q2, the third node Q3, the second level terminal VG2, and the signal output terminal GOUT separately so that the output circuit 14 can control a gate driving signal G1 output from the signal output terminal GOUT according to the second clock signal ck2 at the second clock terminal VCK2, the signal at the second node Q2, the signal at the third node Q3, and the second level signal at the second level terminal VG2. The output circuit 14 may establish or disconnect a signal transmission path between the second clock terminal VCK2 and the signal output terminal GOUT under the control of the signal at the second node Q2. The output circuit 14 may establish or disconnect a signal transmission path between the second level terminal VG2 and the signal output terminal GOUT under the control of the signal at the third node Q3.

Illustratively, when the signal at the second node Q2 is at an active level and the signal at the third node Q3 is at an inactive level, the output circuit 14 may transmit the second clock signal ck2 from the second clock terminal VCK2 to the signal output terminal GOUT as the gate driving signal G1 so that the gate driving signal G1 can be consistent with the second clock signal ck2. Conversely, when the signal at the second node Q2 is at an inactive level and the signal at the third node Q3 is at an active level, the output circuit 14 may transmit the second level signal from the second level terminal VG2 to the signal output terminal GOUT as the gate driving signal G1 so that the gate driving signal G1 can be consistent with the second level signal. The gate driving signal G1 may be used to drive the pixel circuit 50 so that the pixel circuit 50 can drive the light-emitting element to emit light for display. In an optional embodiment, the second clock signal ck2 at the second clock terminal VCK2 includes the active level of the gate driving signal G1, and the second level signal at the second level terminal VG2 is the inactive level of the gate driving signal G1. In another optional embodiment, a period in which the second clock signal ck2 is at the active level of the gate driving signal G1 overlaps with a period in which the signal at the second node Q2 is at an active level so that the signal output terminal GOUT can output the active level of the gate driving signal G1.

It is to be noted that in the preceding description, the consistency between signals refers to the consistency of potential levels of the signals, for example, both being at a logic high level or both being at a logic low level, and is not intended to limit the voltages of the signals to be identical. Due to the influence of transmission impedance and conduction voltage drop, a slight voltage difference is allowed between the signals that remain consistent. Similarly, inconsistency between signals refers to the inconsistency of potential levels of the signals, for example, one being at a logic high level and the other being at a logic low level. When signals are both at a logic high level or both at a logic low level but have a voltage difference due to transmission impedance or conduction voltage drop, the signals can be considered consistent.

On the basis of the preceding description, in the same shift register 101, during at least part of a period in which the signal at the second node Q2 is at an active level and the input signal vin at the signal input terminal VIN is at an inactive level, the first clock signal ck1 at the first clock terminal VCK1 controls the first control circuit 11 to disconnect the signal transmission path between the signal input terminal VIN and the first node Q1, and/or the isolation control signal ct at the isolation control terminal VCT controls the isolation control circuit 13 to disconnect the signal transmission path between the first node Q1 and the second node Q2.

Specifically, the period in which the signal at the second node Q2 is at an active level and the input signal vin at the signal input terminal VIN is at an inactive level, is the period in which the output circuit 14 may transmit the second clock signal ck2 from the second clock terminal VCK2 to the signal output terminal GOUT as the gate driving signal G1 and the input signal vin is inconsistent with the signal at the second node Q2. During at least part of this period, the first control circuit 11 may disconnect the signal transmission path between the signal input terminal VIN and the first node Q1 under the control of the first clock signal ck1 at the first clock terminal VCK1, and/or the isolation control circuit 13 may disconnect the signal transmission path between the first node Q1 and the second node Q2 under the control of the isolation control signal ct at the isolation control terminal VCT. Thus, the signal transmission path between the signal input terminal VIN and the second node Q2 can be effectively disconnected. In this manner, when the signal at the second node Q2 is at an active level and the input signal vin is inconsistent with the signal at the second node Q2, the leakage current between the signal input terminal VIN and the second node Q2 can be reduced. This configuration contributes to maintaining the stability of the signal at the second node Q2 when the signal at the second node Q2 is at the active level, ensuring that the output circuit 14 can stably output the second clock signal ck2 as the gate driving signal G1, thereby improving the stability of the gate driving signal G1, enabling the pixel circuit 50 to operate stably, and further improving the display effect and reliability of the display panel 100. In an embodiment, in the same shift register 101, during at least part of a period in which the signal at the second node Q2 is at an active level, the input signal vin at the signal input terminal VIN is at an inactive level, and the second clock signal ck2 at the second clock terminal VCK2 is at the active level of the gate driving signal G1, the first clock signal ck1 at the first clock terminal VCK1 controls the first control circuit 11 to disconnect the signal transmission path between the signal input terminal VIN and the first node Q1, and/or the isolation control signal ct at the isolation control terminal VCT controls the isolation control circuit 13 to disconnect the signal transmission path between the first node Q1 and the second node Q2.

Illustratively, when both the first clock signal ck1 and the isolation control signal ct are at an active level, both the first control circuit 11 and the isolation control circuit 13 are in an on state. The input signal vin may be transmitted to the first node Q1 through the first control circuit 11 and then to the second node Q2 through the isolation control circuit 13. The signal at the second node Q2 may be consistent with the input signal vin at the signal input terminal VIN, and both are at an active level or both are at an inactive level. Generally, an input signal vin(j) at a signal input terminal VIN(j) of a j-th stage shift register 101(j) is reused as a gate driving signal G1(i) at a signal output terminal GOUT(i) of an i-th stage shift register 101(i). At the same time, the gate driving signals G1 output by the shift registers 101 are sequentially shifted. Accordingly, the active period of the gate driving signal G1(j) at the signal output terminal (j) of the j-th stage shift register 101(j) at least partially does not overlap with the active period of the gate driving signal G1(i) at the signal output terminal (i) of the i-th stage shift register 101(i). That is, the active period of the input signal vin(j) at the j-th stage shift register 101(j) at least partially does not overlap with the active period of the gate driving signal G1(j). Therefore, in the same shift register 101, part of a period in which the input signal vin is at an inactive level and the signal at the second node Q2 is at an active level exists so that the signal output terminal GOUT can output the active level of the second clock signal ck2 as the active level of the gate driving signal G1.

When the input signal vin at the signal input terminal VIN is at an inactive level and the signal at the second node Q2 is at an active level, if the first clock signal ck1 and the isolation control signal ct are still at an active level and control the first control circuit 11 and the isolation control circuit 13 to be in an on state, a current exists between the second node Q2 and the signal input terminal VIN. The signal at the second node Q2 is affected by the input signal vin, causing the signal at the second node Q2 to be unable to maintain a stable active level and affecting the stable output of the active level of the gate driving signal G1 from the signal output terminal GOUT.

In this embodiment, during at least part of a period in which the signal at the second node Q2 is at an active level and the input signal vin at the signal input terminal VIN is at an inactive level, the first clock signal ck1 at the first clock terminal VCK1 may be configured to control the first control circuit 11 to turn off to disconnect the connection path between the signal input terminal VIN and the first node Q1 so that the signal at the first node Q1 cannot be transmitted to the signal input terminal VIN, and the signal at the signal input terminal VIN cannot be transmitted to the first node Q1. This ensures that the potential at the first node Q1 does not jump to an inactive level. On this basis, even if leakage current exists between the second node Q2 and the first node Q1, since the potential level at the first node Q1 remains unchanged, the second node Q2 can be maintained at the active level. This configuration contributes to improving the stability of the signal at the second node Q2, enabling the signal at the second node Q2 to control the signal output terminal GOUT of the output circuit 14 to output a stable gate driving signal G1, and thereby improving the accuracy of the gate driving signal G1 output by the shift register 101. In this manner, the pixel circuits 50 electrically connected to the shift registers G can receive an accurate gate driving signal G1, which facilitates the display accuracy of the display panel 100, thereby improving the display effect of the display panel 100.

Alternatively, during at least part of a period in which the signal at the second node Q2 is at an active level and the input signal vin at the signal input terminal VIN is at an inactive level, the isolation control signal ct at the isolation control terminal VCT may also be configured to control the isolation control circuit 13 to turn off to disconnect the connection path between the first node Q1 and the second node Q2. In this manner, when leakage current exists between the first node Q1 and the signal input terminal VIN, the leakage current does not affect the signal at the second node Q2. This configuration contributes to improving the stability of the signal at the second node Q2, enabling the signal at the second node Q2 to control the signal output terminal GOUT of the output circuit 14 to output a stable gate driving signal G1, and thereby improving the accuracy of the gate driving signal G1 output by the shift register G. In this manner, the pixel circuits 50 electrically connected to the shift registers G can receive an accurate gate driving signal G1, which facilitates the display accuracy of the display panel 100, thereby improving the display effect of the display panel 100.

Alternatively, during at least part of a period in which the signal at the second node Q2 is at an active level and the input signal vin at the signal input terminal VIN is at an inactive level, the first clock signal ck1 at the first clock terminal VCK1 may be configured to control the first control circuit 11 to turn off, and the isolation control signal ct at the isolation control terminal VCT may be configured to control the isolation control circuit 13 to turn off at the same time, so as to disconnect the connection path between the signal input terminal VIN and the first node Q1 and the connection path between the first node Q1 and the second node Q2. In this manner, the stability of the signal at the second node Q2 and the accuracy of the gate driving signal G1 are improved. Thus, the pixel circuits 50 electrically connected to the shift registers G can receive an accurate gate driving signal G1, thereby improving the display effect of the display panel 100.

It can be understood that at least part of a period in which the signal at the second node Q2 is at an active level and the input signal vin at the signal input terminal VIN is at an inactive level may specifically be part or all of the time during which the signal at the second node Q2 is at an active level and the input signal vin at the signal input terminal VIN is at an inactive level. Before and/or after the signal output terminal GOUT of the output circuit 14 outputs the active level of the gate driving signal G1, it is necessary to establish the signal transmission path between the signal input terminal VIN and the first node Q1 and the signal transmission path between the first node Q1 and the second node Q2 so that the signal at the second node Q2 remains consistent with the potential level of the input signal vin at the signal input terminal VIN. Therefore, the signal transmission path between the signal input terminal VIN and the second node Q2 cannot be disconnected for a long time. On this basis, during the period in which the signal at the second node Q2 is at an active level and the input signal vin at the signal input terminal VIN is at an inactive level, the time during which the first clock signal ck1 at the first clock terminal VCK1 controls the first control circuit 11 to disconnect the signal transmission path between the signal input terminal VIN and the first node Q1 and/or the isolation control signal ct at the isolation control terminal VCT controls the isolation control circuit 13 to disconnect the signal transmission path between the first node Q1 and the second node Q2, may be set according to actual needs, and no specific limitation is made here.

It can also be understood that the active levels of the input signal vin, the first clock signal ck1, the second clock signal ck2, the isolation control signal ct, the signal at the first node Q1, and the signal at the second node Q2 may be logic high levels or logic low levels. The active levels of the input signal vin, the first clock signal ck1, the second clock signal ck2, the isolation control signal ct, the signal at the first node Q1, and the signal at the second node Q2 may be the same or different and may be specifically designed according to actual needs. For ease of description, unless otherwise specified, an example in which the active levels of the input signal vin, the first clock signal ck1, the second clock signal ck2, the isolation control signal ct, the signal at the first node Q1, and the signal at the second node Q2 are logic high levels, is used in the embodiments of the present disclosure to illustratively describe the technical solutions of the embodiments of the present disclosure.

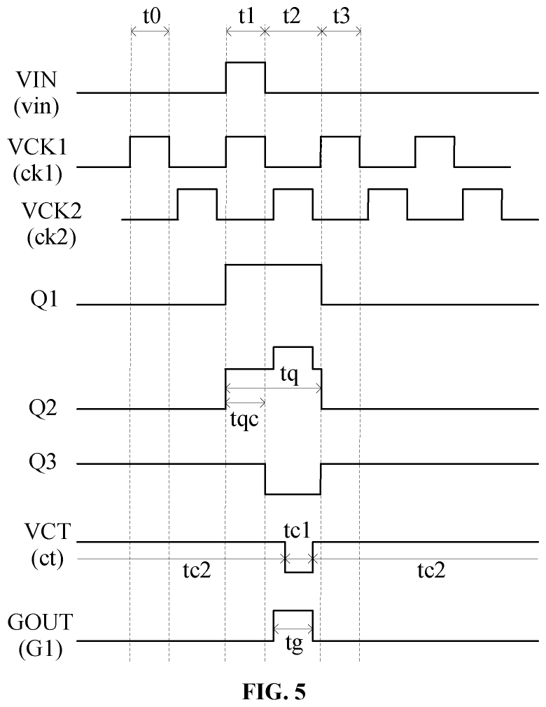

An example in which the active levels related to the shift register 101 are all logic high levels and the inactive levels are all logic low levels is used. FIG. 5 is a first timing graph of a shift register according to an embodiment of the present disclosure, which can be used to drive the shift register 101 provided in FIG. 4. With reference to FIG. 4 and FIG. 5, the operation of the shift register 101 includes a first period t1 and a second period t2. In the second period t2, the signal at the second node Q2 is at a logic high level and the input signal vin at the signal input terminal VIN is at a logic low level, that is, the signal at the second node Q2 is at an active level and the input signal vin at the signal input terminal VIN is at an inactive level. During at least part of the second period t2, the first clock signal ck1 is at an inactive logic low level, and/or the isolation control signal ct is at an inactive logic low level. In this manner, under the control of the first clock signal ck1 and the isolation control signal ct, the first control circuit 11 in this embodiment of the present disclosure can disconnect the transmission path between the first node Q1 and the signal input terminal VIN during at least part of the second period t2; or the isolation control circuit 13 can disconnect the transmission path between the first node Q1 and the second node Q2 during at least part of the second period t2; or the first control circuit 11 can disconnect the transmission path between the first node Q1 and the signal input terminal VIN during at least part of the second period t2, and the isolation control circuit 13 can disconnect the transmission path between the first node Q1 and the second node Q2 during at least part of the second period t2. Through the above manner, the logic high level at the second node Q2 can be prevented from leaking to the first node Q1 and the signal input terminal VIN so that the second node Q2 can stably maintain the logic high level, thereby ensuring that the shift register 101 can stably output the signal from the second clock terminal VCK2 as the gate driving signal G1. The shift register 101 can provide a stable gate driving signal G1 to the pixel circuit 50, achieving the stable operation of the pixel circuit 50.

In an embodiment, during the entire second period t2, at least one of the first clock signal ck1 and the isolation control signal ct is at an inactive logic low level. That is, at any moment in the second period t2, at least one of the first control circuit 11 and the isolation control circuit 13 is turned off, so as to prevent the first control circuit 11 and the isolation control circuit 13 from being turned on at the same time and thus prevent the active logic high level at the second node Q2 from being pulled down to an inactive logic low level by the signal input terminal VIN. In another embodiment, during at least part of the second period t2, both the first clock signal ck1 and the isolation control signal ct are at an inactive logic low level, so as to reduce the leakage current between the signal input terminal VIN and the first node Q1 and the leakage current between the first node Q1 and the second node Q2, thereby reducing the leakage current between the signal input terminal VIN and the second node Q2. This configuration contributes to improving the stability of the signal at the second node Q2. In another embodiment, in the second period t2, the period in which both the first clock signal ck1 and the isolation control signal ct are at an inactive logic low level overlaps with a period in which the second clock signal ck2 at the second clock terminal VCK2 is at an active level. That is, during at least part of the period in which the second node Q2 is at an active level and controls the output circuit 14 to output the active level of the second clock signal ck2 as the active level of the gate driving signal G1, the first control circuit 11 and the isolation control circuit 13 may be turned off at the same time, so as to reduce the leakage current between the signal input terminal VIN and the second node Q2, improve the stability of the second node Q2 when the second node Q2 is at the active level, and thus improve the stability of the gate driving signal G1 when the gate driving signal G1 is at the active level.

It is to be noted that the preceding embodiments only illustratively describe the case in which the active levels are all logic high levels and the inactive levels are all logic low levels, but are not limited thereto. The high/logic low levels of the active level and the inactive level are related to the specific structure of the circuit controlled by the levels. For example, when the controlled circuit includes a transistor and the transistor is a P-type transistor, the active level is a logic low level, and the inactive level is a logic high level. In this case, the logic low level may control the transistor to turn on, and the logic high level may control the transistor to turn off. When the controlled circuit includes a transistor and the transistor is an N-type transistor, the active level is a logic high level, and the inactive level is a logic low level. In this case, the logic high level may control the transistor to turn on, and the logic low level may control the transistor to turn off. In the embodiments of the present disclosure, the high/logic low levels of the active level and the inactive level may be defined according to actual needs.

It is also to be noted that a logic high level and a logic low level refer to a potential level or voltage range used to control a circuit to turn on or turn off, and are not limited to a certain fixed voltage. For example, electrical signals from +15 V to +30 V that can control a circuit to be in the same state may all be logic high-level signals, and electrical signals from −10 V to −5 V that can control a circuit to be in the same state may all be logic low-level signals.

In the display panel provided by the embodiments of the present disclosure, a driving circuit including multiple shift registers is disposed in the display panel so that an output circuit of each shift register can sequentially output an active pulse of a gate driving signal when a second node inside the shift register is at an active level, thereby ensuring the orderly operation of pixel circuits and enabling the display panel to display images. In addition, a first control circuit is disposed between the signal input terminal and the first node of the shift register, and an isolation control circuit is disposed between the first node and the second node. During at least part of a period in which the signal at the second node is at an active level and the input signal at the signal input terminal is at an inactive level, the first clock signal at the first clock terminal controls the first control circuit to disconnect the signal transmission path between the signal input terminal and the first node, and/or the isolation control signal at the isolation control terminal controls the isolation control circuit to disconnect the signal transmission path between the first node and the second node. This configuration cuts off the signal transmission path between the second node and the signal input terminal so that the signal at the second node can be maintained at the active level. This contributes to improving the stability of the signal at the second node, enabling the signal at the second node to control the signal output terminal of the output circuit to output a stable gate driving signal, and thereby improving the accuracy of the gate driving signal output by the shift register. Furthermore, when the gate driving signals output by the shift registers are used to perform row-by-row scanning on the pixel circuits in the display panel, each pixel circuit can receive an accurate gate driving signal. This contributes to improving the accuracy of light emission of the pixels, thereby improving the display effect of the display panel.

The preceding description only describes the on/off states of the first control circuit 11 and the isolation control circuit 13 during the period in which the signal at the second node Q2 is at an active level and the input signal vin at the signal input terminal VIN is at an inactive level. The on/off states of the first control circuit 11 and the isolation control circuit 13 during the period in which the input signal vin at the signal input terminal VIN is at an active level will be described below. In an optional embodiment, with continued reference to FIG. 4 and FIG. 5, in the same shift register 101, during at least part of a period in which the input signal vin at the signal input terminal VIN is at an active level, the first clock signal ck1 at the first clock terminal VCK1 controls the first control circuit 11 to establish the signal transmission path between the signal input terminal VIN and the first node Q1, and the isolation control signal ct at the isolation control terminal VCT controls the isolation control circuit 13 to establish the signal transmission path between the first node Q1 and the second node Q2.

Illustratively, an example in which the active levels are all logic high levels and the inactive levels are all logic low levels is used. With reference to FIG. 4 and FIG. 5, during the first period t1, the input signal vin at the signal input terminal VIN is at an active level, and both the first clock signal ck1 and the isolation control signal ct are at an active logic high level and may control the first control circuit 11 and the isolation control circuit 13 to turn on. In this case, the input signal vin at the signal input terminal VIN may be transmitted to the second node Q2 through the first control circuit 11 and the isolation control circuit 13 so that the potentials at the second node Q2 and the first node Q1 are both at an active level. The output circuit 14 may output the electrical signal from the second clock terminal VCK2 under the control of the active level at the second node Q2. When the second clock signal ck2 provided by the second clock terminal VCK2 is at an active level, the signal output terminal GOUT may output an active pulse of the gate driving signal G1, thereby ensuring the orderly operation of the pixel circuits and enabling the display panel to display images. In an embodiment, the input signal vin is at an active level in the first period t1, that is, the first period t1 is the active period of the input signal vin.

It is to be noted that at least part of a period in which the input signal vin at the signal input terminal VIN is at an active level includes part of a period in which the input signal vin is at an active level or the entire period in which the input signal vin is at an active level. The preceding description only illustratively describes that the first control circuit 11 and the isolation control circuit 13 are controlled to be in an on state during the entire period in which the input signal vin is at an active level. In other optional embodiments, the first control circuit 11 and the isolation control circuit 13 may also be controlled to turn on during part of the period in which the input signal vin is at an active level. For example, during the first period t1 (including the start moment and the end moment of the active period of the input signal vin), the period in which both the first clock signal ck1 and the isolation control signal ct are at an active level is after the start moment of the active period of the input signal vin. In this case, after a period of time following the transition of the input signal vin at the signal input terminal VIN from an inactive level to an active level, the first control circuit 11 and the isolation control circuit 13 are turned on. The second node Q2 may receive the active level of the input signal vin and control the output circuit 14 to output the second clock signal ck2 as the gate driving signal G1. For another example, during the first period t1 (including the start moment and the end moment of the active period of the input signal vin), the period in which both the first clock signal ck1 and the isolation control signal ct are at an active level overlaps with the start moment of the active period of the input signal vin, and the period in which both the first clock signal ck1 and the isolation control signal ct are at an active level is before the end moment of the active period of the input signal vin. In this case, during a period of time starting from the start moment when the input signal vin at the signal input terminal VIN transitions from an inactive level to an active level, the first control circuit 11 and the isolation control circuit 13 are turned on. The second node Q2 may receive the active level of the input signal vin. Before the input signal vin transitions to an inactive level, the first clock signal ck1 and/or the isolation control signal ct transition to an inactive level, which can cause the first control circuit 11 and/or the isolation control circuit 13 to turn off and thus cut off the signal path between the second node Q2 and the signal input terminal VIN in advance. In this manner, when the input signal vin subsequently transitions from an active level to an inactive level, the electrical signal at the second node Q2 is not affected. Thus, the accuracy of the signal at the second node Q2 can be ensured so that the output circuit 14 outputs an accurate gate driving signal G1 according to the signal at the second node Q2, ensuring the stable operation of the pixel circuit 50 electrically connected to the signal output terminal GOUT and improving the display effect and reliability of the display panel 100.

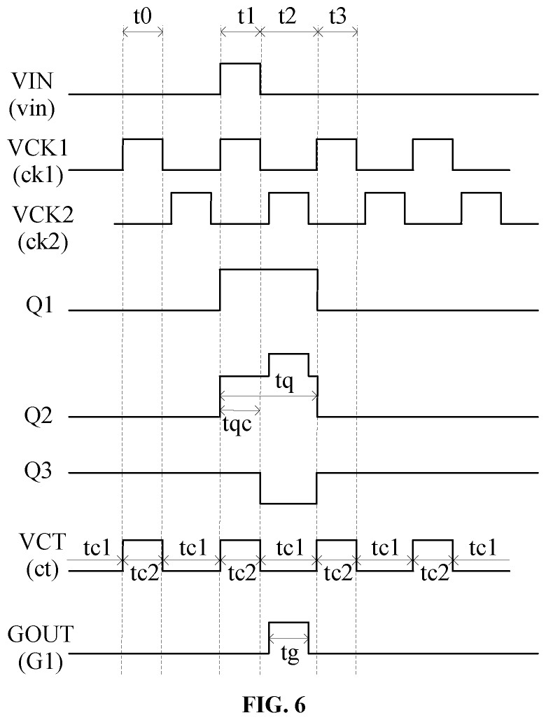

The preceding description describes the on/off states of the first control circuit 11 and the isolation control circuit 13 during the period in which the signal at the second node Q2 is at an active level and/or the input signal vin is at an active level. The on/off states of the first control circuit 11 and the isolation control circuit 13 during a period in which both the signal at the second node Q2 and the input signal vin are at an inactive level will be described below. In an optional embodiment, FIG. 6 is a second timing graph of a shift register according to an embodiment of the present disclosure. With reference to FIG. 4 to FIG. 6, in the same shift register 101, in a refresh phase of a frame of image, during at least part of a period after a gate driving signal G1 at the signal output terminal GOUT transitions from an active level to an inactive level, the first clock signal ck1 at the first clock terminal VCK1 controls the first control circuit 11 to establish the signal transmission path between the signal input terminal VIN and the first node Q1, and the isolation control signal at the isolation control terminal VCT controls the isolation control circuit 13 to establish the signal transmission path between the first node Q1 and the second node Q2.

The refresh phase of a frame of image refers to a phase from the end of light emission of the last row of pixels in the previous display frame to the end of light emission of the last row of pixels in the current display frame. In an embodiment, during the refresh phase of a frame of image, the pixel circuit 50 can receive the gate driving signal G1 and write a corresponding data signal so that the pixel circuit 50 can provide a corresponding drive current according to the data signal to drive the light-emitting element to display a corresponding gray scale. In another embodiment, during the refresh phase of a frame of image, each shift register 101 sequentially outputs an active pulse of the gate driving signal G1, and the shift register 101 outputs only one active pulse of the gate driving signal G1.

Illustratively, an example in which the active levels are all logic high levels and the inactive levels are all logic low levels is used. With reference to FIG. 4 to FIG. 6, during the refresh phase of a frame of image, during at least part of a period after the gate driving signal G1 at the signal output terminal GOUT transitions from an active logic high level to an inactive logic low level, for example, during a period t3 after the gate driving signal G1 transitions from an active logic high level to an inactive logic low level, the isolation control signal ct at the isolation control terminal VCT controls the isolation control circuit 13 to establish the signal transmission path between the first node Q1 and the second node Q2 so that the signal at the second node Q2 can be consistent with the signal at the first node Q1. At the same time, during the period t3, the first clock signal ck1 at the first clock terminal VCK1 controls the first control circuit 11 to establish the signal transmission path between the signal input terminal VIN and the first node Q1 so that the signal at the first node Q1 is consistent with the input signal vin at the signal input terminal VIN. In this manner, the active logic high level at the second node Q2 can be discharged to the signal input terminal VIN through the first node Q1 so that the second node Q2 is pulled down to an inactive logic low level. Under the control of the inactive level at the second node Q2, the output circuit 14 cannot continue outputting the active logic high level of the second clock signal ck2. Thus, the signal output terminal GOUT outputs only one active pulse during the refresh phase of a frame of image, thereby avoiding a display abnormality caused by continuous output of active pulses by the signal output terminal GOUT. Furthermore, it is possible to prevent the output circuit 14 from still transmitting the active logic high level of the second clock signal ck2 to the signal output terminal GOUT when the signal output terminal GOUT outputs an inactive logic low level, which would otherwise cause a short circuit between the second clock terminal VCK2 and the second level terminal VG2, forming an abnormal large current and damaging the circuit.

It can be understood that at least part of a period after the gate driving signal G1 at the signal output terminal GOUT transitions from an active level to an inactive level may be the period t3 or may be the entire period after the gate driving signal G1 transitions from an active level to an inactive level during the refresh phase of a frame of image. Both the first control circuit 11 and the isolation control circuit 13 are controlled to be in an on state during at least part of the period after the gate driving signal G1 at the signal output terminal GOUT transitions from an active level to an inactive level so that the potentials at the second node Q2 and the first node Q1 can be inactive levels. When the second node Q2 is at an inactive level, the output circuit 14 may stop outputting the active level of the second clock signal ck2 to the signal output terminal GOUT under the control of the inactive level at the second node Q2, so as to ensure that the gate driving signal G1 includes only one active pulse during the refresh phase of a frame of image. This configuration contributes to the accuracy of the gate driving signal G1 output from the signal output terminal GOUT.

In an optional embodiment, during the refresh phase of a frame of image, after the gate driving signal G1 at the signal output terminal GOUT transitions from an active logic high level to an inactive logic low level, the period (tc2) in which the isolation control signal ct is at an active level overlaps with the period in which the first clock signal ck1 is at an active level. That is, the period in which the first clock signal ck1 at the first clock terminal VCK1 controls the first control circuit 11 to establish the signal transmission path between the signal input terminal VIN and the first node Q1 overlaps with the period in which the isolation control signal at the isolation control terminal VCT controls the isolation control circuit 13 to establish the signal transmission path between the first node Q1 and the second node Q2. In this manner, the first control circuit 11 and the isolation control circuit 13 turn on at the same time, writing the inactive level of the input signal vin to the second node Q2, thereby preventing the signal at the second node Q2 from remaining at an active level for a long time and from causing the signal output terminal GOUT to output multiple active pulses. Illustratively, with reference to FIG. 6, the isolation control signal ct includes an active level and an inactive level, and the active level and the inactive level of the isolation control signal ct may change alternately. The period (tc2) in which the isolation control signal ct is at an active level may overlap with the period in which the first clock signal ck1 is at an active level. On this basis, the isolation control terminal VCT may be reused as the first clock terminal VCK1, and the isolation control signal ct may be reused as the first clock signal ck1.

In another optional embodiment, during the refresh phase of a frame of image, after the gate driving signal G1 at the signal output terminal GOUT transitions from an active logic high level to an inactive logic low level, the start moment of the period in which the first clock signal ck1 at the first clock terminal VCK1 controls the first control circuit 11 to establish the signal transmission path between the signal input terminal VIN and the first node Q1, and the start moment of the period in which the isolation control signal at the isolation control terminal VCT controls the isolation control circuit 13 to establish the signal transmission path between the first node Q1 and the second node Q2 are both before the moment when the second clock signal ck2 at the second clock terminal VCK2 transitions to an active level for the first time. That is, during the refresh phase of a frame of image, after the gate driving signal G1 transitions to an inactive logic low level, the moment when the first clock signal ck1 transitions to an active level for the first time and the moment when the isolation control signal ct transitions to an active level for the first time are both before the moment when the second clock signal ck2 transitions to an active level for the first time. In this manner, after the gate driving signal G1 transitions to an inactive logic low level and before the second clock signal ck2 transitions to an active level for the first time, the signal at the second node Q2 can be made consistent with the inactive level of the input signal vin, and it is ensured that the gate driving signal G1 includes only one active pulse during the refresh phase of a frame of image.

With continued reference to FIG. 4 to FIG. 6, in another optional embodiment, in the same shift register 101, in a refresh phase of a frame of image, during at least part of a period before the input signal vin at the signal input terminal VIN transitions from an inactive level to an active level, the first clock signal ck1 at the first clock terminal VCK1 controls the first control circuit 11 to establish the signal transmission path between the signal input terminal VIN and the first node Q1, and the isolation control signal at the isolation control terminal VCT controls the isolation control circuit 13 to establish the signal transmission path between the first node Q1 and the second node Q2.

Illustratively, an example in which the active levels are all logic high levels and the inactive levels are all logic low levels is used. With reference to FIG. 4 to FIG. 6, in the refresh phase of a frame of image, during at least part of a period before the input signal vin at the signal input terminal VIN transitions from an inactive logic low level to an active logic high level, for example, during part of the period t0 before the input signal vin at the signal input terminal VIN transitions from an inactive logic low level to an active logic high level, both the first clock signal ck1 and the isolation control signal ct are at an active level. The first clock signal ck1 controls the first control circuit 11 to turn on, and the isolation control signal ct controls the isolation control circuit 13 to turn on so that the inactive level of the input signal vin at the signal input terminal VIN is transmitted to the first node Q1 and the second node Q2. In this manner, before the input signal vin at the signal input terminal VIN transitions to an active level, the potentials at the first node Q1 and the second node Q2 are maintained at an inactive level. Under the action of the inactive level at the second node Q2, the output circuit 14 does not output the active level of the second clock signal ck2 from the second clock terminal VCK2 to the signal output terminal GOUT. Thus, it is ensured that the gate driving signal G1 does not transition to an active level before the input signal vin transitions to an active level during the refresh phase of a frame of image, which contributes to improving the accuracy of the gate driving signal G1 output by the shift register 101.

It can be understood that at least part of a period before the input signal vin at the signal input terminal VIN transitions from an inactive level to an active level may be the period t0 or may be the entire period before the input signal vin transitions from an inactive level to an active level during the refresh phase of a frame of image. Both the first control circuit 11 and the isolation control circuit 13 are controlled to be in an on state during at least part of the period before the input signal vin at the signal input terminal VIN transitions from an inactive level to an active level so that the potentials at the second node Q2 and the first node Q1 can be inactive levels. When the second node Q2 is at an inactive level, the output circuit 14 may stop outputting the active level of the second clock signal ck2 to the signal output terminal GOUT under the control of the inactive level at the second node Q2, so as to ensure that the gate driving signal G1 does not transition to an active level before the input signal vin transitions to an active level during the refresh phase of a frame of image. This contributes to the accuracy of the gate driving signal G1 output from the signal output terminal GOUT.

In an optional embodiment, in the same shift register 101, in a refresh phase of a frame of image, before a period t1 in which the input signal vin is at an active level, at least one active pulse of the first clock signal ck1 is included. The isolation control signal ct may remain at an active level during at least part of the period in which the first clock signal ck1 is at an active level so that an overlap exists between the period in which the first clock signal ck1 is at an active level and the period (tc2) in which the isolation control signal ct is at an active level. In this case, the isolation control circuit 13 and the first control circuit 11 turn on at the same time, and the signal at the second node Q2 is at an inactive level. This configuration can ensure that the output circuit 14 does not output an active pulse of the gate driving signal G1 before the period t1 in which the input signal vin is at an active level.

In another optional embodiment, the isolation control terminal VCT is reused as the first clock terminal VCK1, and the isolation control signal ct is the same as the first clock signal ck1. That is, when the first clock signal ck1 is at an active level, the isolation control signal ct is also at an active level; when the first clock signal ck1 is at an inactive level, the isolation control signal ct is also at an inactive level. In this manner, when the first control circuit 11 is turned on, the isolation control circuit 13 can also be controlled to turn on, ensuring that the level of the input signal vin at the signal input terminal VIN can be transmitted to the second node Q2. When the first control circuit 11 is turned off, the isolation control circuit 13 can also be controlled to turn off. In this manner, the leakage current between the second node Q2 and the signal input terminal VIN can be reduced when the second node Q2 is at an active level, which contributes to maintaining the stability when the second node Q2 is at an active level, thereby improving the stability of the gate driving signal G1 when the gate driving signal G1 is at an active level.

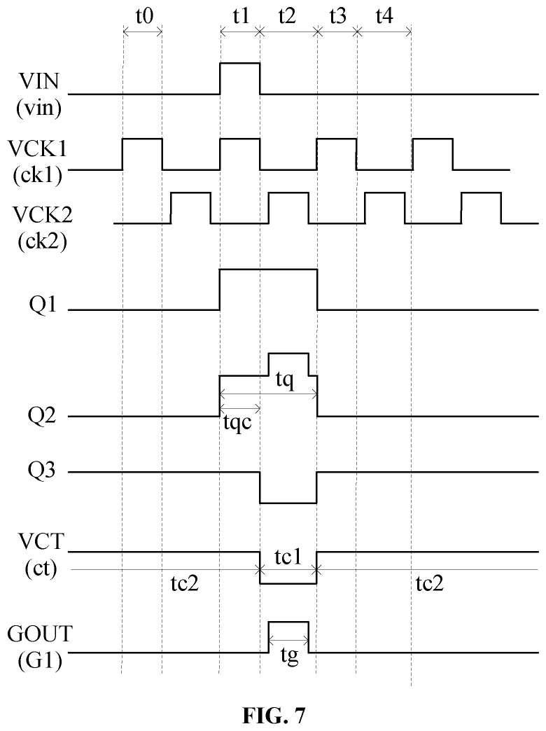

On the basis of the preceding embodiments, FIG. 7 is a third timing graph of a shift register according to an embodiment of the present disclosure. With reference to FIG. 4 and FIG. 7, in the same shift register 101, a period tc1 in which the isolation control signal ct at the isolation control terminal VCT is at an inactive level overlaps with a period tq in which the signal at the second node Q2 is at an active level, and a period tc2 in which the isolation control signal ct at the isolation control terminal VCT is at an active level does not overlap with a period tg in which the gate driving signal G1 at the signal output terminal GOUT is at an active level.

Specifically, during the period tc1 in which the isolation control signal ct is at an inactive level, the isolation control signal ct may control the isolation control circuit 13 to disconnect the signal transmission path between the first node Q1 and the second node Q2. During the period tc2 in which the isolation control signal ct is at an active level, the isolation control signal ct may control the isolation control circuit 13 to establish the signal transmission path between the first node Q1 and the second node Q2. The period tc1 in which the isolation control signal ct at the isolation control terminal VCT is at an inactive level is controlled to overlap with the period tq in which the signal at the second node Q2 is at an active level. In this manner, when the signal at the second node Q2 is at an active level, the inactive level of the isolation control signal ct can control the isolation control circuit 13 to disconnect the signal transmission path between the first node Q1 and the second node Q2 so that the signal at the first node Q1 cannot affect the second node Q2. This configuration ensures that the second node Q2 can stably remain at the active level, thereby improving the accuracy of the gate driving signal G1 output by the output circuit 14. At the same time, the period tc2 in which the isolation control signal ct at the isolation control terminal VCT is at an active level is configured to be non-overlapping with the period tg in which the gate driving signal G1 at the signal output terminal GOUT is at an active level. In this manner, when the output circuit 14 outputs an active level from the signal output terminal GOUT under the control of the active level at the second node Q2, the isolation control signal ct can be maintained at an inactive level to control the isolation control circuit 13 to disconnect the signal transmission path between the first node Q1 and the second node Q2. In this manner, the active level at the second node Q2 cannot be transmitted to the first node Q1 through the isolation control circuit 13. The signal at the second node Q2 can be stably maintained at the active level, which contributes to improving the stability of the gate driving signal G1, and avoids leakage current at the second node Q2 when the signal output terminal GOUT outputs the active level, thereby preventing signal fluctuations at the second node Q2 from affecting the output of a stable gate driving signal G1 by the output circuit 14.

In an optional embodiment, the period tc1 in which the isolation control signal ct at the isolation control terminal VCT is at an inactive level partially overlaps with the period tq in which the signal at the second node Q2 is at an active level. That is, during the period tq in which the signal at the second node Q2 is at an active level, part of a period in which the isolation control signal ct at the isolation control terminal VCT is at an inactive level exists, and part of a period tqc in which the isolation control signal ct at the isolation control terminal VCT is at an active level also exists. In other words, the period tc2 in which the isolation control signal ct is at an active level also partially overlaps with the period tq in which the signal at the second node Q2 is at an active level. The period tq in which the signal at the second node Q2 is at an active level includes part of a period tqc. During this part of the period tqc, both the signal at the second node Q2 and the isolation control signal ct at the isolation control terminal VCT are at an active level. During the refresh phase of a frame of image, the period tqc is positioned before the period tc1 in which the isolation control signal ct is at an inactive level, and the period tqc overlaps with the period in which the input signal vin at the signal input terminal VIN is at an active level.

Illustratively, an example in which the active levels are all logic high levels and the inactive levels are all logic low levels is used. With reference to FIG. 4 and FIG. 7, during the period tqc, the input signal vin, the first clock signal ck1, and the isolation control signal ct are all at an active logic high level. The first control circuit 11 may be turned on under the control of the active logic high level of the first clock signal ck1, and the isolation control circuit 13 may be turned on under the control of the active logic high level of the isolation control signal ct so that the active logic high level of the input signal vin at the signal input terminal VIN can be transmitted to the second node Q2 through the first control circuit 11 and the isolation control circuit 13, thereby adjusting the signal at the second node Q2 to an active level. At the same time, during the period tqc, both the second clock signal ck2 and the gate driving signal G1 are at an inactive logic low level. After the period tqc, during the period tc1, the isolation control signal ct is at an inactive logic low level and may control the isolation control circuit 13 to disconnect the signal transmission path between the first node Q1 and the second node Q2 so that the signal at the second node Q2 is not affected by the signal at the first node Q1 and remains at an active level. At the same time, during the period tc1, both the second clock signal ck2 and the gate driving signal G1 include an active logic high level so that the output circuit 14 can stably output an active pulse of the gate driving signal G1 under the control of the stable active level at the second node Q2.

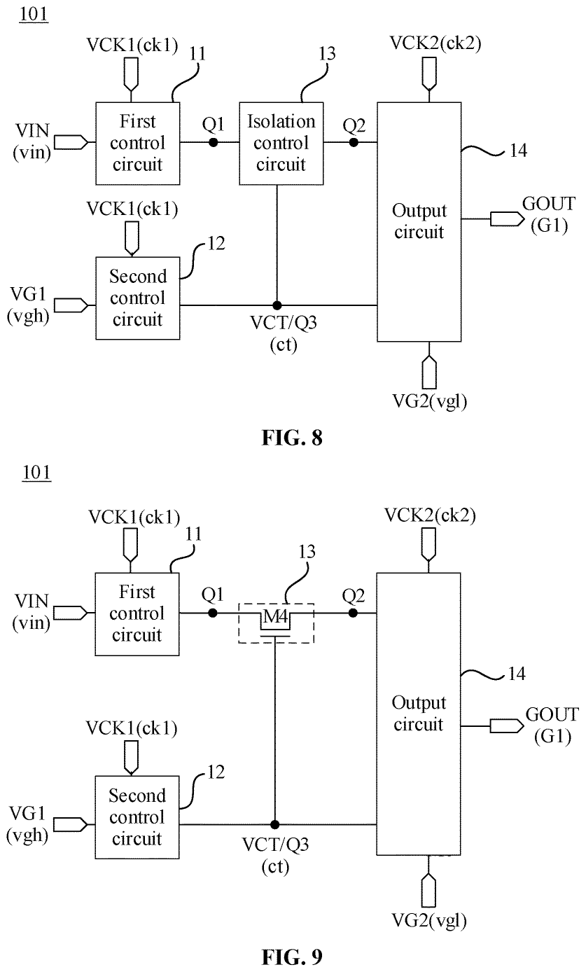

On the basis of the preceding embodiments, FIG. 8 is a second schematic diagram illustrating the circuit structure of a shift register according to an embodiment of the present disclosure. With reference to FIG. 7 and FIG. 8, in the same shift register 101, the isolation control terminal VCT is reused as the third node Q3.

Illustratively, an example in which the active levels are all logic high levels and the inactive levels are all logic low levels is used. With reference to FIG. 7 and FIG. 8, during the first period t1, the input signal vin at the signal input terminal VIN and the first clock signal ck1 are at an active logic high level. In this case, the first control circuit 11 and the second control circuit 12 are turned on. The first control circuit 11 may transmit the active logic high level of the input signal vin to the first node Q1. The second control circuit 12 may transmit the first level signal (that is, a logic high-level signal vgh) from the first level terminal VG1 to the third node Q3. The active logic high level at the third node Q3 may control the isolation control circuit 13 to turn on, thereby enabling the active level at the first node Q1 to be transmitted to the second node Q2. In this case, both the signal at the second node Q2 and the signal at the third node Q3 are at an active logic high level. The second clock signal ck2 at the second clock terminal VCK2 is at an inactive logic low level. The output circuit 14 may simultaneously output the inactive logic low level of the second clock signal CK2 and the second level signal (that is, a logic low-level signal vgl) from the second level terminal VG2.

During the second period t2, both the input signal vin at the signal input terminal VIN and the first clock signal ck1 transition to an inactive logic low level. The first clock signal ck1 controls the first control circuit 11 and the second control circuit 12 to turn off. The signal at the first node Q1 remains at an active logic high level. The signal at the third node Q3 may transition to an inactive logic low level. The inactive logic low level at the third node Q3 may control the isolation control circuit 13 to turn off so that the isolation control circuit 13 disconnects the signal transmission path between the first node Q1 and the second node Q2. The active logic high level at the second node Q2 cannot be discharged to the signal input terminal VIN through the isolation control circuit 13 and the first control circuit 11. Thus, it can be ensured that the active level at the second node Q2 can remain stable during this period (that is, the second period t2) and is not affected by the signal at the first node Q1 and the input signal vin at the signal input terminal VIN. During the second period t2, the second clock signal ck2 includes an active level. Under the action of the active level at the second node Q2 and the inactive level at the third node Q3, the output circuit 14 can transmit the active level of the second clock signal ck2 to the signal output terminal GOUT, and the active logic high level at the second node Q2 remains stable. This configuration contributes to improving the stability of the active level at the signal output terminal GOUT, thereby improving the display effect and reliability of the display panel 100. In an embodiment, the shift register 101 may include a reset circuit (not shown in FIG. 8) electrically connected to the third node Q3. When the signal at the first node Q1 is at an active level and the input signal vin and/or the first clock signal ck1 is at an inactive level, the reset circuit can control the third node Q3 to transition to an inactive level.

During a third period t3, the first clock signal ck1 transitions to an active logic high level, and the second clock signal ck2 transitions to an inactive logic low level. The first clock signal ck1 controls the first control circuit 11 and the second control circuit 12 to turn on so that the third node Q3 can receive the first level signal (that is, a logic high-level signal vgh) from the first level terminal VG1. The active logic high level at the third node Q3 may control the isolation control circuit 13 to turn on so that the active logic high level at the second node Q2 can be discharged to the signal input terminal VIN through the isolation control circuit 13 and the first control circuit 11. After the signal at the second node Q2 is discharged, the signal at the second node Q2 is maintained at an inactive logic low level. Under the action of the inactive logic low level at the second node Q2 and the active logic high level at the third node Q3, the output circuit 14 outputs the second level signal (that is, a logic low-level signal vgl) from the second level terminal VG2 as the gate driving signal G1.

During a fourth period t4, the first clock signal ck1 transitions to an inactive logic low level, and the second clock signal ck2 transitions to an active logic high level. The first clock signal ck1 controls the first control circuit 11 and the second control circuit 12 to turn off. In this case, the signals at the first node Q1 and the second node Q2 are still at an inactive logic low level. The signal at the third node Q3 may remain unchanged and is still at an active logic high level so that the signal at the third node Q3 can control the isolation control circuit 13 to turn on. In this case, under the action of the inactive logic low level at the second node Q2 and the active logic high level at the third node Q3, the output circuit 14 continues to output the second level signal (that is, a logic low-level signal vgl) from the second level terminal VG2 as the gate driving signal G1. After the fourth period t4, as long as the input signal vin remains at an inactive level, no matter how the first clock signal ck1 and the second clock signal ck2 change, the signals at the first node Q1 and the second node Q2 are both at an inactive level, and the signal at the third node Q3 is at an active level. The output circuit 14 can always output the inactive level from the second level terminal VG2 as the inactive level of the gate driving signal G1.

In this manner, the isolation control terminal VCT is configured to be reused as the third node Q3 so that the period tc1 in which the isolation control signal ct at the isolation control terminal VCT is at an inactive level can overlap with the period tq in which the signal at the second node Q2 is at an active level, and the period tc2 in which the isolation control signal ct at the isolation control terminal VCT is at an active level does not overlap with the period tg in which the gate driving signal G1 at the signal output terminal GOUT is at an active level. It is not required to set a separate control circuit and control signal for providing the isolation control signal ct at the isolation control terminal VCT, which can simplify the circuit structure and control timing of the shift register 101.

In an optional embodiment, FIG. 9 is a third schematic diagram illustrating the circuit structure of a shift register according to an embodiment of the present disclosure. As shown in FIG. 9, the isolation control circuit 13 includes an isolation control transistor M4. A first electrode of the isolation control transistor M4 is electrically connected to the first node Q1, a second electrode of the isolation control transistor M4 is electrically connected to the second node Q2, and a gate of the isolation control transistor M4 is electrically connected to the third node Q3.

Illustratively, an example in which the active levels are all logic high levels, the inactive levels are all logic low levels, and the isolation control transistor M4 is an N-type transistor is used. With reference to FIG. 9, when the signal at the third node Q3 is at an active level, the signal at the third node Q3 may control the isolation control transistor M4 to turn on, thereby transmitting the signal at the first node Q1 to the second node Q2, or transmitting the signal at the second node Q2 to the first node Q1. Thus, when it is necessary to reset the second node Q2, the active level at the second node Q2 can be discharged through the isolation control circuit 13 to reset the signal at the second node Q2. When the signal at the third node Q3 is at an inactive level, the signal at the third node Q3 may control the isolation control transistor M4 to turn off so that the signal at the first node Q1 cannot be transmitted to the second node Q2, or the signal at the second node Q2 cannot be transmitted to the first node Q1. Thus, when the signal at the second node Q2 is at an active level, the signal at the second node Q2 can be stably maintained at the active level, improving the stability of the signal at the second node Q2.

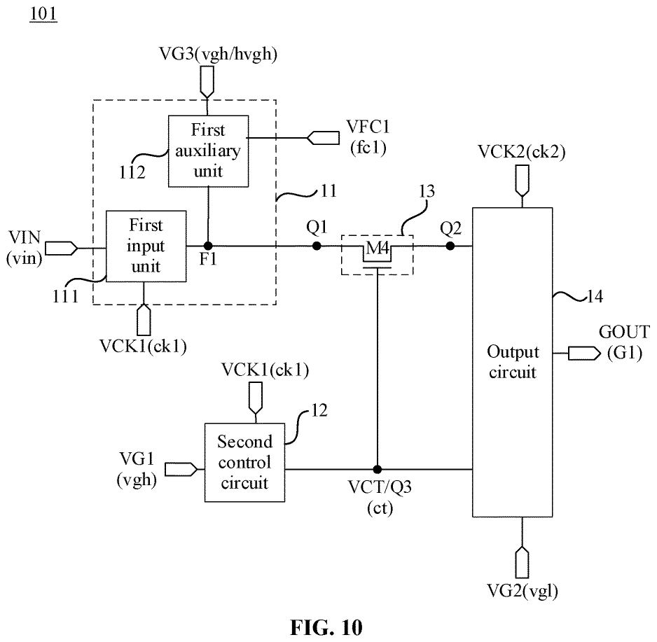

Optionally, FIG. 10 is a fourth schematic diagram illustrating the circuit structure of a shift register according to an embodiment of the present disclosure. As shown in FIG. 10, the shift register 101 also includes a third level terminal VG3 and a first auxiliary control terminal VFC1. The first control circuit 11 includes a first input unit 111 and a first auxiliary unit 112. A first terminal of the first input unit 111 is electrically connected to the signal input terminal VIN, a second terminal of the first input unit 111 is coupled to the first node Q1, and a control terminal of the first input unit 111 is electrically connected to the first clock terminal VCK1. A first terminal of the first auxiliary unit 112 is electrically connected to the third level terminal VG3, a second terminal of the first auxiliary unit 112 and the second terminal of the first input unit 111 are electrically connected to a first auxiliary node F1, and a control terminal of the first auxiliary unit 112 is electrically connected to the first auxiliary control terminal VFC1.

In the same shift register 101, during at least part of a period in which the signal at the second node Q2 is at an active level and the input signal vin at the signal input terminal VIN is at an inactive level, a first auxiliary control signal fc1 at the first auxiliary control terminal VFC1 controls the first auxiliary unit 112 to establish a signal transmission path between the third level terminal VG3 and the first auxiliary node F1.

The third level terminal VG3 may receive a third level signal. The third level signal may be a fixed level. The fixed level may be the active level of the first node Q1. When the active level of the first node Q1 is a logic high level, the third level signal may be a logic high-level signal vgh or an enhanced high-level signal hvgh. When the active level of the first node Q1 is a logic low level, the third level signal may be a logic low-level signal vgl or an enhanced low-level signal lvgl. The first auxiliary control terminal VFC1 may receive a varying first auxiliary control signal fc1 to control the first auxiliary unit 112 to be in an on or off state under the action of different levels of the first auxiliary control signal fc1.

Specifically, the first auxiliary signal at the first auxiliary control terminal VFC1 may control the first auxiliary unit 112 to establish or disconnect the signal transmission path between the third level terminal VG3 and the first auxiliary node F1. When the first auxiliary signal at the first auxiliary control terminal VFC1 controls the first auxiliary unit 112 to turn on, the third level signal from the third level terminal VG3 may be transmitted to the first auxiliary node F1 through the first auxiliary unit 112. Since the first auxiliary node F1 is coupled to the first node Q1 (it is possible that the first auxiliary node F1 is directly electrically connected to the first node Q1, or the first auxiliary node F1 is indirectly electrically connected to the first node Q1), the first auxiliary node F1 may transmit the third level signal to the first node Q1 so that the signal at the first node Q1 is maintained at the third level signal. In this manner, during at least part of a period in which the signal at the second node Q2 is at an active level and the input signal vin at the signal input terminal VIN is at an inactive level, the third level signal from the third level terminal VG3 is written to the first auxiliary node F1. This configuration contributes to reducing the leakage current of the first node Q1, improving the stability of the signal at the first node Q1, reducing the leakage current between the second node Q2 and the first node Q1, and improving the stability of the signal at the second node Q2. In an embodiment, the period in which the first auxiliary signal fc1 is at an inactive level may overlap with the period in which the first clock signal ck1 is at an active level. When the first auxiliary signal fc1 at the first auxiliary control terminal VFC1 controls the first auxiliary unit 112 to turn off, the third level signal from the third level terminal VG3 cannot be transmitted to the first auxiliary node F1 through the first auxiliary unit 112. In this case, the first clock signal ck1 controls the first input unit 111 to turn on, and the signals at the second node Q2 and the first node Q1 may be consistent with the input signal vin at the signal input terminal VIN, so as to reset the first node Q1 and the second node Q2.

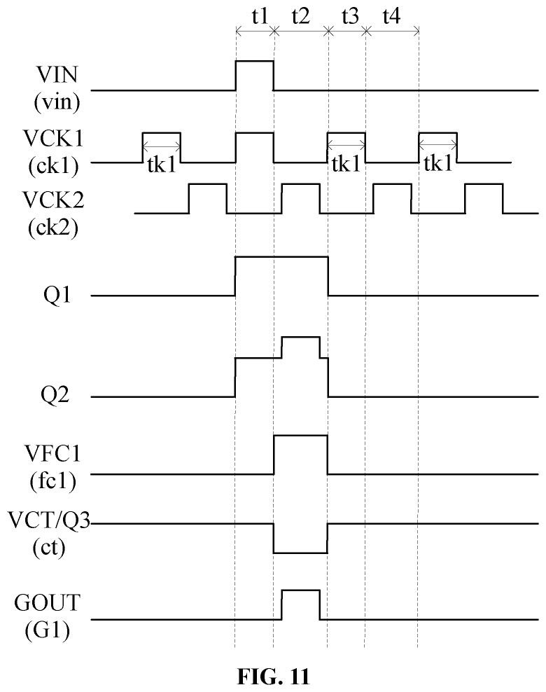

Illustratively, an example in which the active levels are all logic high levels and the inactive levels are all logic low levels is used. FIG. 11 is a fourth timing graph of a shift register according to an embodiment of the present disclosure. With reference to FIG. 10 and FIG. 11, during at least part of a period (which may be part of a period or the entire period) in which the signal at the second node Q2 is at an active level and the input signal at the signal input terminal VIN is at an inactive level, the first auxiliary control signal fc1 at the first auxiliary control terminal VFC1 is at an active logic high level and can control the first auxiliary unit 112 to turn on. The third level signal from the third level terminal VG3 may be transmitted to the first auxiliary node F1 through the first auxiliary unit 112 so that the signal at the first node Q1 is maintained at an active level. This configuration contributes to reducing the leakage current transmitted from the first node Q1 to the signal input terminal VIN through the first input unit 111, improving the stability of the signal at the first node Q1, and at the same time reducing the leakage current between the second node Q2 and the first node Q1, thereby further improving the stability of the signal at the second node Q2.

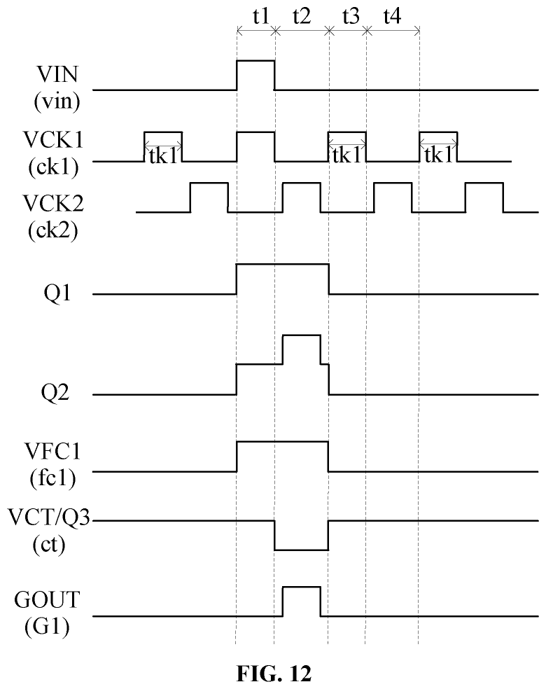

In an optional embodiment, FIG. 12 is a fifth timing graph of a shift register according to an embodiment of the present disclosure. With continued reference to FIG. 10 to FIG. 12, in the same shift register 101, during a period in which the input signal vin at the signal input terminal VIN is at an inactive level and the first clock signal ck1 at the first clock terminal VCK1 is at an active level, the first auxiliary control signal fc1 at the first auxiliary control terminal VFC1 controls the first auxiliary unit 112 to disconnect the signal transmission path between the third level terminal VG3 and the first auxiliary node F1.

Illustratively, an example in which the active levels are all logic high levels and the inactive levels are all logic low levels is used. With reference to FIG. 10 to FIG. 12, during a period tk1 in which the input signal vin at the signal input terminal VIN is at an inactive logic low level and the first clock signal ck1 at the first clock terminal VCK1 is at an active logic high level, the first auxiliary control signal fc1 is at an inactive logic low level and may control the first auxiliary unit 112 to disconnect the signal transmission path between the third level terminal VG3 and the first auxiliary node F1 so that the active logic high level of the third level signal from the third level terminal VG3 cannot be transmitted to the first auxiliary node F1, nor can the active logic high level of the third level signal from the third level terminal VG3 be transmitted to the first node Q1. In this case, the signal at the first node Q1 is not affected by the third level signal. At the same time, during the period tk1, the input signal vin at the signal input terminal VIN is at an inactive level. The first input unit 111 is turned on under the action of the first clock signal ck1. In this case, the input signal vin may be transmitted to the first node Q1 through the first input unit 111. The first auxiliary control signal fc1 is controlled to be at an inactive level during the period tk1 so that the first input unit 111 and the first auxiliary unit 112 can be prevented from being turned on at the same time when the input signal vin at the signal input terminal VIN is at an inactive level, thereby preventing a short circuit between the active logic high level at the third level terminal VG3 and the inactive logic low level at the signal input terminal VIN and avoiding the formation of an abnormal large current and the damage to the first control circuit 11. In addition, during the period tk1, the isolation control signal ct may include an active level to control the isolation control circuit 13 to turn on. The inactive level of the input signal vin may be transmitted to the second node Q2 through the first input unit 111 and the isolation control circuit 13 so that the first node Q1 and the second node Q2 can change following the input signal vin when the input signal vin is at an inactive level and the first clock signal ck1 is at an active level. This configuration contributes to improving the accuracy of the signal at the second node Q2 and preventing the first auxiliary unit 112 from affecting the reset of the signals at the first node Q1 and the second node Q2 and thereby preventing abnormality in the signals at the first node Q1 and the second node Q2.

It can be understood that during a period in which the input signal vin at the signal input terminal VIN is at an active level and the first clock signal ck1 at the first clock terminal VCK1 is at an active level, the first auxiliary control signal fc1 at the first auxiliary control terminal VFC1 may control the first auxiliary unit 112 to disconnect the signal transmission path between the third level terminal VG3 and the first auxiliary node F1, as shown in FIG. 11, or the first auxiliary control signal fc1 at the first auxiliary control terminal VFC1 may control the first auxiliary unit 112 to establish the signal transmission path between the third level terminal VG3 and the first auxiliary node F1, as shown in FIG. 12, which is not limited in the embodiment of the present disclosure.

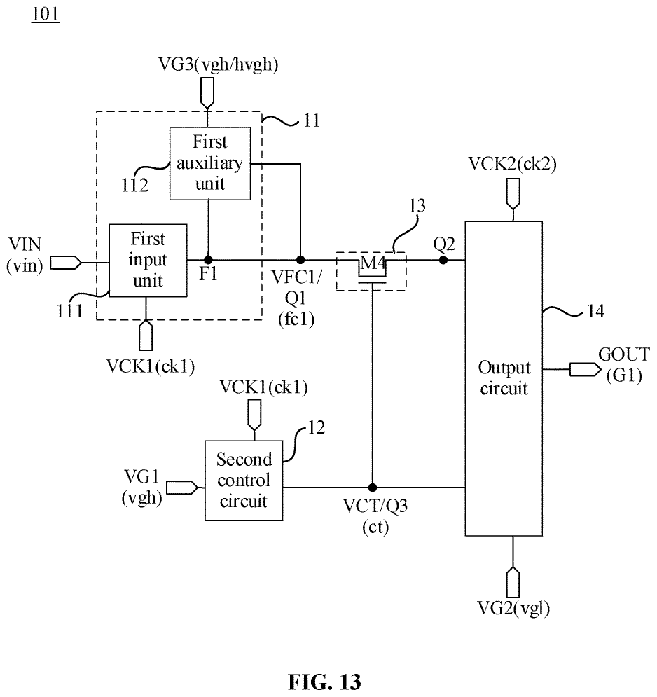

In an optional embodiment, FIG. 13 is a fifth schematic diagram illustrating the circuit structure of a shift register according to an embodiment of the present disclosure. As shown in FIG. 13, the first auxiliary control terminal VFC1 is reused as the first node Q1.

Illustratively, an example in which the active levels are all logic high levels and the inactive levels are all logic low levels is used. With reference to FIG. 12 and FIG. 13, before the period tk1 (where the input signal vin is at an inactive logic low level and the first clock signal ck1 is at an active logic high level), if the signal at the first node Q1 is at an active level, after the period tk1 is entered, the first clock signal ck1 is at an active level and may control the first input unit 111 to turn on. The active level at the first node Q1 may be discharged to the signal input terminal VIN through the first input unit 111. When the potential at the first node Q1 is pulled down, the potential of the first auxiliary control signal fc1 is also pulled down, and the first auxiliary unit 112 may be controlled to disconnect the signal transmission path between the third level terminal VG3 and the first auxiliary node F1. In this case, the first node Q1 may be stably maintained at an inactive level and is not affected by the signal from the third level terminal VG3, so as to achieve the reset of the first node Q1 and the second node Q2. In this manner, the first auxiliary control terminal VFC1 is configured to be reused as the first node Q1 so that the reset of the first node Q1 and the second node Q2 can be achieved without separately setting a control circuit or a signal line for providing the first auxiliary control signal fc1 at the first auxiliary control terminal VFC1. Moreover, the circuit structure of the shift register 101 can be simplified.

In addition, during the second period t2 in which the signal at the second node Q2 is at an active level and the input signal vin at the signal input terminal VIN is at an inactive level, the signal at the first node Q1 is at an active logic high level, that is, the first auxiliary control signal fc1 is also at an active logic high level. The active logic high level of the third level signal from the third level terminal VG3 is written to the first node Q1. This configuration contributes to reducing the leakage current of the first node Q1, improving the stability of the signal at the first node Q1, thereby reducing the leakage current between the second node Q2 and the first node Q1 and improving the stability of the signal at the second node Q2.

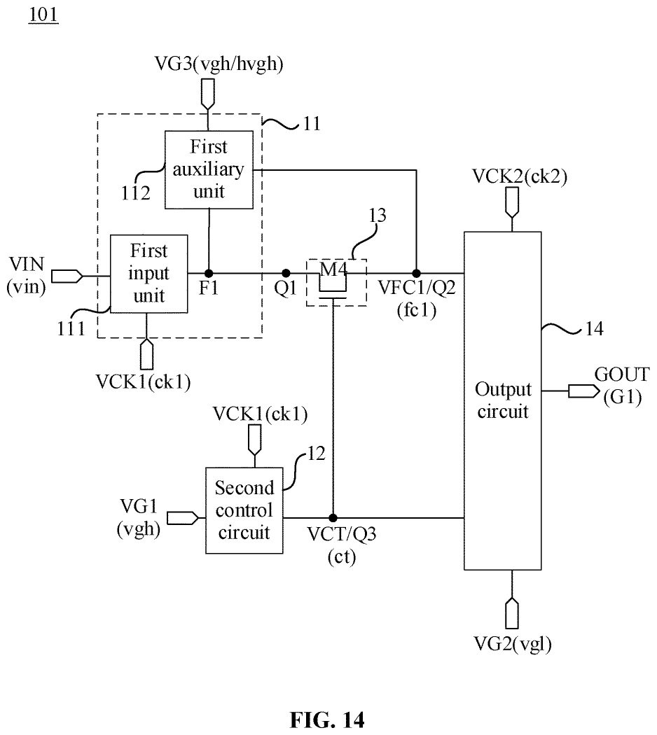

In another optional embodiment, FIG. 14 is a sixth schematic diagram illustrating the circuit structure of a shift register according to an embodiment of the present disclosure. As shown in FIG. 14, the first auxiliary control terminal VFC1 is reused as the second node Q2.

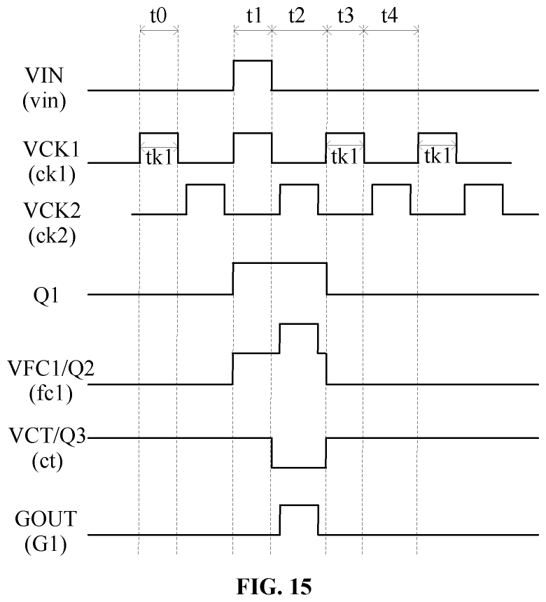

Illustratively, an example in which the active levels are all logic high levels and the inactive levels are all logic low levels is used. FIG. 15 is a sixth timing graph of a shift register according to an embodiment of the present disclosure. With reference to FIG. 14 and FIG. 15, during the period tk1 (where the input signal vin is at an inactive logic low level and the first clock signal ck1 is at an active logic high level), the signals at the first node Q1 and the second node Q2 are both at an inactive logic low level. The first auxiliary control terminal VFC1 is reused as the second node Q2. The inactive logic low level at the second node Q2 may control the first auxiliary unit 112 to disconnect the signal transmission path between the third level terminal VG3 and the first auxiliary node F1 so that the first node Q1 cannot receive the active logic high level of the third level signal. At the same time, the active level of the first clock signal ck1 may control the first input unit 111 to turn on. The inactive logic low level of the input signal vin at the signal input terminal VIN may be transmitted to the first node Q1 through the first input unit 111 and then to the second node Q2 through the isolation control circuit 13 so that the first node Q1 and the second node Q2 are stably maintained at an inactive logic low level. This configuration contributes to improving the reliability of the first node Q1 and the second node Q2 and avoiding the influence on the signal at the second node Q2 caused by the transmission of the active logic high level of the third level signal to the first node Q1. In this manner, the first auxiliary control terminal VFC1 is configured to be reused as the second node Q2 so that the reset of the first node Q1 and the second node Q2 can be achieved without separately setting a control circuit or a signal line for providing the first auxiliary control signal fc1 at the first auxiliary control terminal VFC1. Moreover, the circuit structure of the shift register 101 can be simplified.

In addition, during the second period t2 in which the signal at the second node Q2 is at an active level and the input signal vin at the signal input terminal VIN is at an inactive level, the signal at the second node Q2 is at an active logic high level, that is, the first auxiliary control signal fc1 is also at an active logic high level. The active logic high level of the third level signal from the third level terminal VG3 is written to the first node Q1. This configuration contributes to reducing the leakage current of the first node Q1, improving the stability of the signal at the first node Q1, thereby reducing the leakage current between the second node Q2 and the first node Q1 and improving the stability of the signal at the second node Q2.

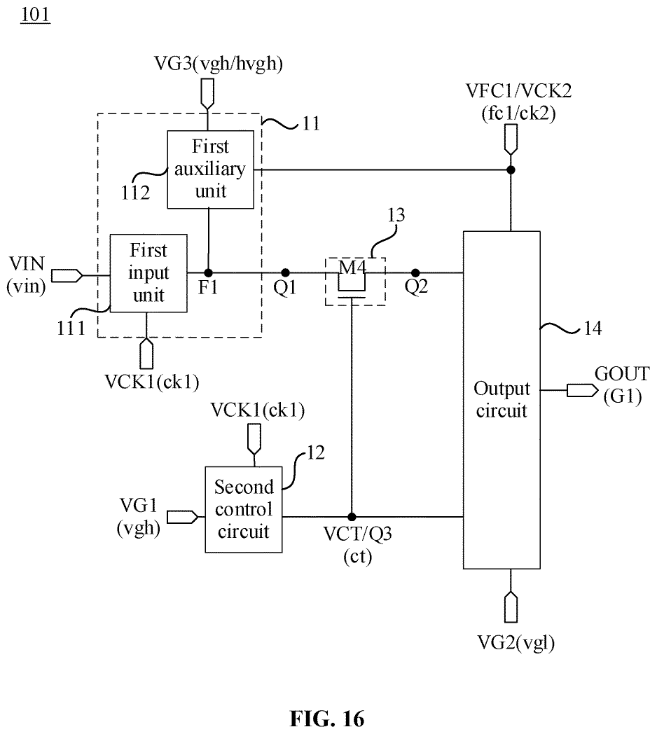

In another optional embodiment, FIG. 16 is a seventh schematic diagram illustrating the circuit structure of a shift register according to an embodiment of the present disclosure. As shown in FIG. 16, the first auxiliary control terminal VFC1 is reused as the second clock terminal VCK2.

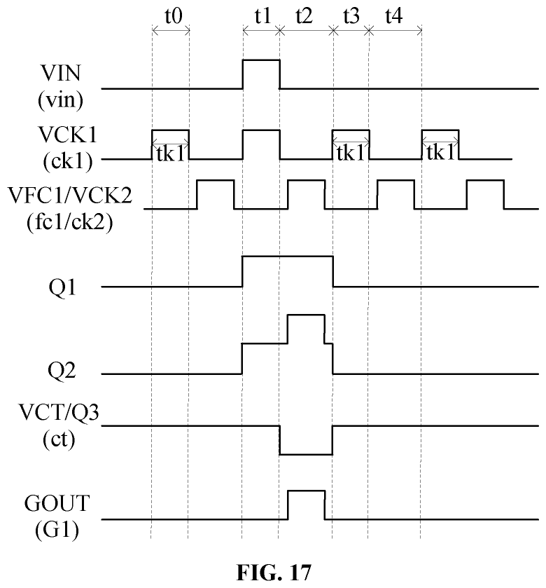

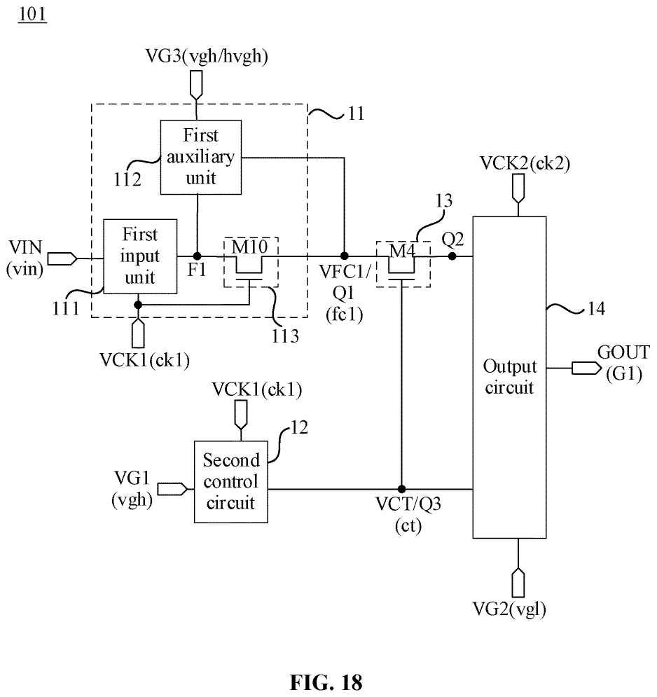

Illustratively, an example in which the active levels are all logic high levels and the inactive levels are all logic low levels is used. FIG. 17 is a seventh timing graph of a shift register according to an embodiment of the present disclosure. With reference to FIG. 16 and FIG. 17, when the first clock signal ck1 at the first clock terminal VCK1 is at an active level, the second clock signal ck2 at the second clock terminal VCK2 is at an inactive level. When the first clock signal ck1 at the first clock terminal VCK1 is at an inactive level, the second clock signal ck2 at the second clock terminal VCK2 includes an active level. Therefore, during the period tk1 (where the input signal vin is at an inactive logic low level and the first clock signal ck1 is at an active logic high level), the inactive level of the second clock signal ck2 may control the first auxiliary unit 112 to disconnect the signal transmission path between the third level terminal VG3 and the first auxiliary node F1. This configuration contributes to improving the stability of the signal at the first node Q1 and avoiding the influence on the signal at the first node Q1 caused by the transmission of third level signal from the third level terminal VG3 to the first auxiliary node F1 and thus avoiding poor reliability of the signals at the first node Q1 and the second node Q2. In this manner, the first auxiliary control terminal VFC1 is configured to be reused as the second clock terminal VCK2 so that the reset of the first node Q1 and the second node Q2 can be achieved without separately setting a control circuit or a signal line for providing the first auxiliary control signal fc1 at the first auxiliary control terminal VFC1. Moreover, the circuit structure of the shift register 101 can be simplified.

In addition, during the second period t2 in which the signal at the second node Q2 is at an active level and the input signal vin at the signal input terminal VIN is at an inactive level, the second clock signal ck2 includes an active logic high level, that is, the first auxiliary control signal fc1 also includes an active logic high level. The active logic high level of the third level signal from the third level terminal VG3 is written to the first node Q1. This configuration contributes to reducing the leakage current of the first node Q1, improving the stability of the signal at the first node Q1, thereby reducing the leakage current between the second node Q2 and the first node Q1 and improving the stability of the signal at the second node Q2.

It can be understood that the preceding description only uses the example in which the first auxiliary node F1 is directly electrically connected to the first node Q1 for illustration. In other optional embodiments, the first auxiliary node F1 may also be indirectly electrically connected to the first node Q1. In another optional embodiment, FIG. 18 is an eighth schematic diagram illustrating the circuit structure of a shift register according to an embodiment of the present disclosure. As shown in FIG. 18, the first control circuit 11 also includes a second input unit 113. A first terminal of the second input unit 113 and the second terminal of the first input unit 111 are electrically connected to the first auxiliary node F1. A second terminal of the second input unit 113 is electrically connected to the first node Q1, and a control terminal of the second input unit 113 is electrically connected to the first clock terminal VCK1.

Illustratively, an example in which the active levels are all logic high levels and the inactive levels are all logic low levels is used. With reference to FIG. 12 and FIG. 18, during the second period t2 in which the signals at the first node Q1 and the second node Q2 are both at an active level and the input signal vin at the signal input terminal VIN and the first clock signal ck1 are both at an inactive level, both the first input unit 111 and the second input unit 113 are turned off, and the first auxiliary unit 112 is turned on. The active logic high level of the third level signal is transmitted to the first auxiliary node F1 so that the signal at the first auxiliary node F1 is at an active logic high level. In this case, the signals at the first auxiliary node F1 (the first terminal of the second input unit 113) and the first node Q1 (the second terminal of the second input unit 113) are both at an active logic high level, which can effectively reduce the leakage current between the first auxiliary node F1 and the first node Q1 and improve the stability of the signal at the first node Q1. In addition, the voltage difference between the control terminal and the first terminal or the second terminal of the second input unit 113 is relatively large, which contributes to controlling the second input unit 113 to be completely turned off, further reducing the current leaked from the first node Q1 to the signal input terminal VIN through the second input unit 113 and the first input unit 111, and improving the stability of the signal at the first node Q1.

On the basis of the preceding embodiments, with continued reference to FIG. 18, the second input unit 113 includes a second input transistor M10. A first electrode of the second input transistor M10 is electrically connected to the first auxiliary node F1, a second electrode of the second input transistor M10 is electrically connected to the first node Q1, and a gate of the second input transistor M10 is electrically connected to the first clock terminal VCK1.

Specifically, when the level of the first clock signal ck1 is at an active level, the first clock signal ck1 may control the second input transistor M10 to turn on, thereby transmitting the signal at the first node Q1 to the first auxiliary node F1, or transmitting the signal at the first auxiliary node F1 to the first node Q1. Thus, when it is necessary to transmit the input signal vin at the signal input terminal VIN to the first node Q1, the input signal vin transmitted to the first auxiliary node F1 can be further transmitted to the first node Q1 through the second input unit 113. When the signal of the first clock signal ck1 is at an inactive level, the first clock signal ck1 may control the second input transistor M10 to turn off, thereby preventing the signal at the first node Q1 from being transmitted to the first auxiliary node F1, or preventing the signal at the first auxiliary node F1 from being transmitted to the first node Q1. Thus, when it is necessary to maintain the second node Q2 and the first node Q1 at an active level, this configuration can improve the stability of the signals at the first node Q1 and the second node Q2 and prevent the signal at the first node Q1 from leaking to the first auxiliary node F1 through the second input transistor M10.

Illustratively, an example in which the active levels are all logic high levels and the inactive levels are all logic low levels is used. With reference to FIG. 12 and FIG. 18, during the second period t2 in which the signals at the first node Q1 and the second node Q2 are both at an active level and the input signal vin at the signal input terminal VIN and the first clock signal ck1 are both at an inactive level, the first clock signal ck1 at the gate of the second input transistor M10 is at an inactive logic low level. The signals at the first auxiliary node F1 and the first node Q1 at two ends of the second input transistor M10 are both at an active logic high level and have a relatively larger voltage difference with the gate. This configuration contributes to controlling the second input transistor M10 to be completely turned off, further reducing the current leaked from the first node Q1 to the signal input terminal VIN through the second input unit 113 and the first input unit 111, and improving the stability of the signal at the first node Q1.

In an optional embodiment, with continued reference to FIG. 18, the second input transistor M10 is an N-type transistor. In the same shift register 101, during at least part of a period in which the signal at the second node Q2 is at an active level and the input signal vin at the signal input terminal VIN is at an inactive level, the voltage difference between the first clock signal ck1 and the first auxiliary node F1 is less than zero, and the voltage difference between the first clock signal ck1 and the first node Q1 is also less than zero.

Illustratively, an example in which the active levels are all logic high levels and the inactive levels are all logic low levels is used. With reference to FIG. 12 and FIG. 18, during the second period t2 in which the signals at the first node Q1 and the second node Q2 are both at an active level and the input signal vin at the signal input terminal VIN and the first clock signal ck1 are both at an inactive level, the first clock signal ck1 includes an inactive logic low level. The signals at the first auxiliary node F1 and the first node Q1 at two ends of the second input transistor M10 both include an active logic high level. The voltage difference between the first clock signal ck1 and the first auxiliary node F1 is less than zero so that the voltage difference between the gate and the first electrode of the second input transistor M10 is less than zero. The voltage difference between the first clock signal ck1 and the first node Q1 is also less than zero so that the voltage difference between the gate and the second electrode of the second input transistor M10 is also less than zero. In this manner, it can be ensured that the voltage differences between the gate and the first electrode and between the gate and the second electrode of the second input transistor M10 in all shift registers 101 are less than the threshold voltage of the second input transistor M10 (the threshold voltage of an N-type transistor is greater than zero) so that the second input transistor M10 is in a completely off state. This configuration can effectively reduce the leakage current between the first node Q1 and the first auxiliary node F1 and enable the first node Q1 to stably remain at the active level, thereby improving the stability of the signal at the first node Q1.

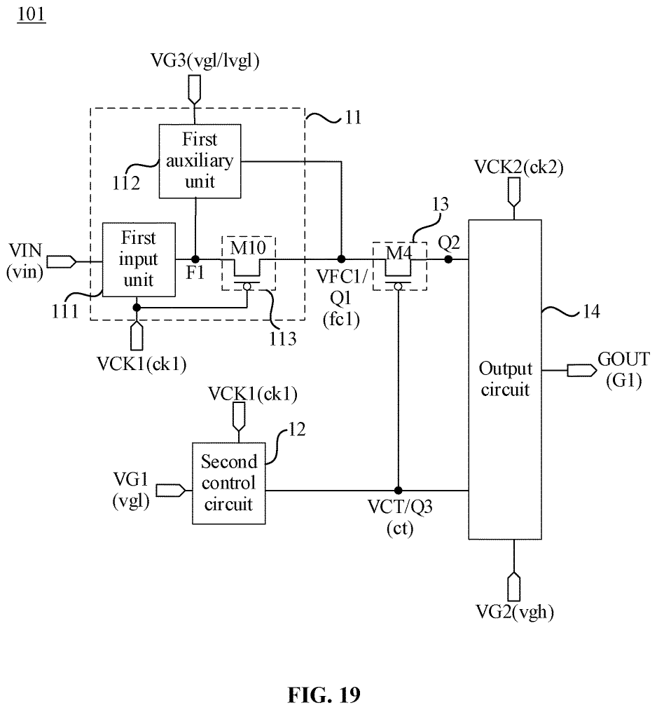

In another optional embodiment, FIG. 19 is a ninth schematic diagram illustrating the circuit structure of a shift register according to an embodiment of the present disclosure. As shown in FIG. 19, the second input transistor M10 is a P-type transistor. In the same shift register 101, during at least part of a period in which the signal at the second node Q2 is at an active level and the input signal vin at the signal input terminal VIN is at an inactive level, the voltage difference between the first clock signal ck1 and the first auxiliary node F1 is greater than zero, and the voltage difference between the first clock signal ck1 and the first node Q1 is also greater than zero.

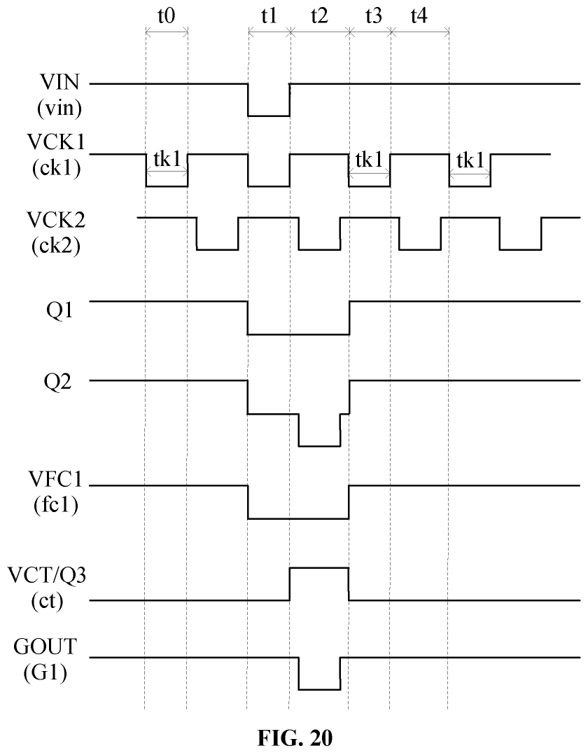

Illustratively, an example in which the active levels are all logic low levels and the inactive levels are all logic high levels is used. FIG. 20 is an eighth timing graph of a shift register according to an embodiment of the present disclosure. With reference to FIG. 19 and FIG. 20, during the second period t2 in which the signals at the first node Q1 and the second node Q2 are both at an active level and the input signal vin at the signal input terminal VIN and the first clock signal ck1 are both at an inactive level, the first clock signal ck1 includes an inactive logic high level. The signals at the first auxiliary node F1 and the first node Q1 at two ends of the second input transistor M10 both include an active logic low level. The voltage difference between the first clock signal ck1 and the first auxiliary node F1 is greater than zero so that the voltage difference between the gate and the first electrode of the second input transistor M10 is greater than zero. The voltage difference between the first clock signal ck1 and the first node Q1 is also greater than zero so that the voltage difference between the gate and the second electrode of the second input transistor M10 is also greater than zero. In this manner, it can be ensured that the voltage differences between the gate and the first electrode and between the gate and the second electrode of the second input transistor M10 in all shift registers 101 are greater than the threshold voltage of the second input transistor M10 (the threshold voltage of a P-type transistor is less than zero) so that the second input transistor M10 is in a completely off state. This configuration can also effectively reduce the leakage current between the first node Q1 and the first auxiliary node F1 and enable the first node Q1 to remain at the active level, thereby improving the stability of the signal at the first node Q1.

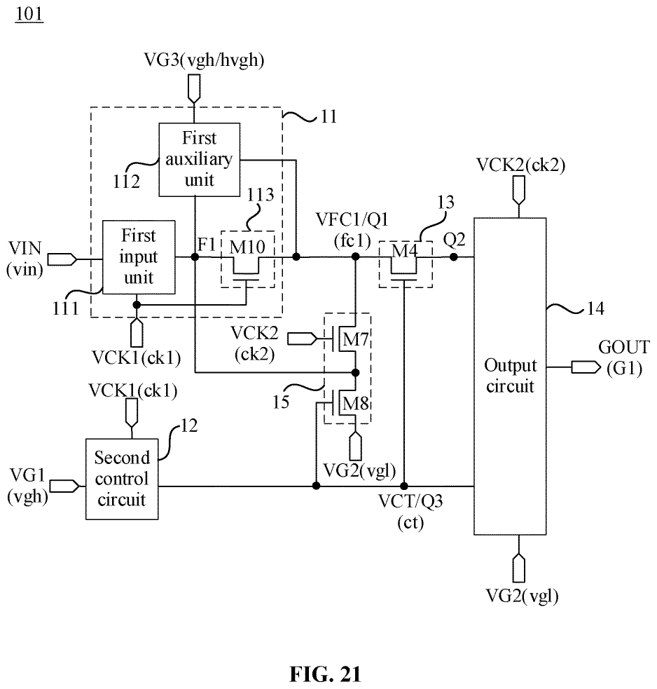

In another optional embodiment, FIG. 21 is a tenth schematic diagram illustrating the circuit structure of a shift register according to an embodiment of the present disclosure. As shown in FIG. 21, the shift register 101 also includes a first reset circuit 15. The first reset circuit 15 includes a first reset transistor M7 and a second reset transistor M8. A first electrode of the first reset transistor M7 is coupled to the first node Q1. A second electrode of the first reset transistor M7 and a first electrode of the second reset transistor M8 are electrically connected to the first auxiliary node F1. A gate of the first reset transistor M7 is electrically connected to the second clock terminal VCK2. A second electrode of the second reset transistor M8 is electrically connected to the second level terminal VG2, and a gate of the second reset transistor M8 is electrically connected to the third node Q3.

Illustratively, an example in which the active levels are all logic high levels and the inactive levels are all logic low levels is used. With reference to FIG. 12 and FIG. 21, the first reset circuit 15 may transmit the inactive logic low level of the second level signal from the second level terminal VG2 to the first node Q1 when both the second clock signal ck2 at the second clock terminal VCK2 and the signal at the third node Q3 are at an active logic high level. That is, the first reset circuit 15 can reset the first node Q1 to an inactive logic low level during other periods in which the second clock signal ck2 is at an active logic high level, except for the second period t2. During the second period t2 in which the signals at the first node Q1 and the second node Q2 are both at an active level and the input signal vin at the signal input terminal VIN and the first clock signal ck1 are both at an inactive level, the signals at the first node Q1, the second node Q2, and the first auxiliary node F1 are all at an active logic high level. The active level of the second clock signal ck2 controls the first reset transistor M7 to turn on, and the inactive level at the third node Q3 controls the second reset transistor M8 to turn off. The second electrode of the first reset transistor M7 and the first electrode of the second reset transistor M8 are configured to be electrically connected to the first auxiliary node F1 so that the signal at the second electrode of the first reset transistor M7 can be stably maintained at an active logic high level. This configuration contributes to reducing the leakage current generated from the first node Q1 to the second level terminal VG2 through the first reset transistor M7 and the second reset transistor M8, and maintaining the stability of the signals at the first node Q1 and the second node Q2.

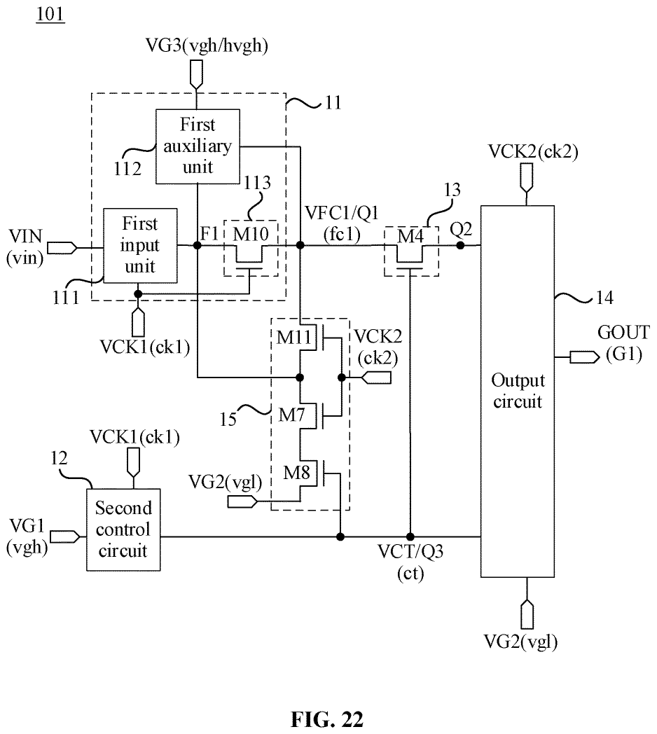

In another optional embodiment, FIG. 22 is an eleventh schematic diagram illustrating the circuit structure of a shift register according to an embodiment of the present disclosure. As shown in FIG. 22, the shift register 101 also includes a first reset circuit 15. The first reset circuit 15 includes a first reset transistor M7, a second reset transistor M8, and a third reset transistor M11. A first electrode of the third reset transistor M11 is electrically connected to the first node Q1. A second electrode of the third reset transistor M11 and a first electrode of the first reset transistor M7 are electrically connected to the first auxiliary node F1. A gate of the third reset transistor M11 and a gate of the first reset transistor M7 are both electrically connected to the second clock terminal VCK2. A second electrode of the first reset transistor M7 is electrically connected to a first electrode of the second reset transistor M8. A second electrode of the second reset transistor M8 is electrically connected to the second level terminal VG2, and a gate of the second reset transistor M8 is electrically connected to the third node Q3.

Illustratively, an example in which the active levels are all logic high levels and the inactive levels are all logic low levels is used. With reference to FIG. 12 and FIG. 22, the first reset transistor M7, the second reset transistor M8, and the third reset transistor M11 in the first reset circuit 15 are all N-type transistors. Thus, when the signals at the first node Q1, the second node Q2, and the first auxiliary node F1 are all at an active logic high level and the second clock signal ck2 is at an inactive level, for example, during the first period t1, the voltage difference between the second clock signal ck2 and the first node Q1 is less than zero, and the voltage difference between the second clock signal ck2 and the first auxiliary node F1 is also less than zero. That is, the voltage differences between the gate and the first electrode and between the gate and the second electrode of the third reset transistor M11 are both less than the threshold voltage of the third reset transistor M11 (the threshold voltage of an N-type transistor is greater than zero) so that the third reset transistor M11 is in a completely off state. This configuration can effectively reduce the leakage current generated from the first node Q1 to the second level terminal VG2 through the third reset transistor M11 and maintain the stability of the signals at the first node Q1 and the second node Q2.

It can be understood that the first reset transistor M7, the second reset transistor M8, and the third reset transistor M11 in the first reset circuit 15 may also be P-type transistors. In this case, the active level is a logic low level, and the inactive level is a logic high level. Since the principle is the same, no further elaboration shall be made in the embodiment of the present disclosure.

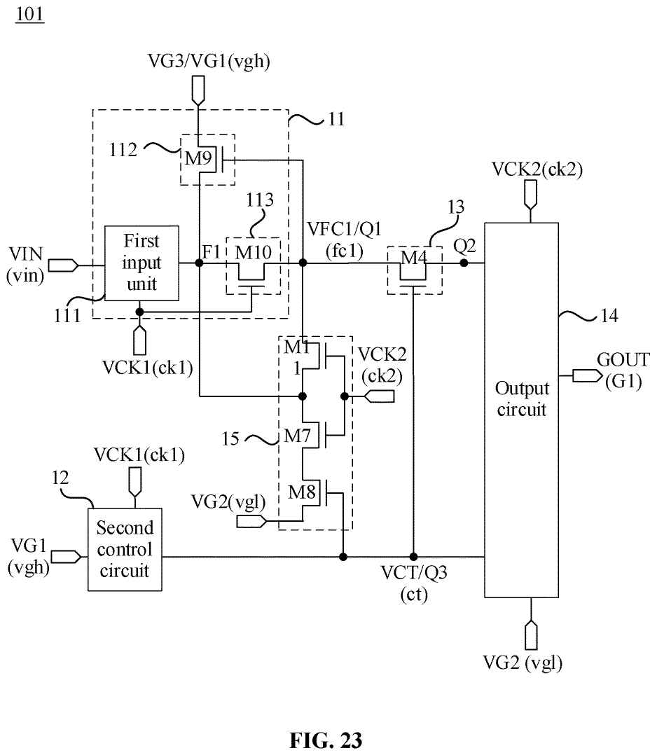

In another optional embodiment, FIG. 23 is a twelfth schematic diagram illustrating the circuit structure of a shift register according to an embodiment of the present disclosure. As shown in FIG. 23, the first auxiliary unit 112 includes a first auxiliary transistor M9. A first electrode of the first auxiliary transistor M9 is electrically connected to the third level terminal VG3, a second electrode of the first auxiliary transistor M9 is electrically connected to the first auxiliary node F1, and a gate of the first auxiliary transistor M9 is electrically connected to the first auxiliary control terminal VFC1.

Illustratively, an example in which the active levels are all logic high levels and the inactive levels are all logic low levels is used. With reference to FIG. 23, the first auxiliary transistor M9 is an N-type transistor. When the first auxiliary control signal fc1 at the first auxiliary control terminal VFC1 is at an active logic high level, the first auxiliary control signal fc1 may control the first auxiliary transistor M9 to turn on. In this case, the active logic high level of the third level signal from the third level terminal VG3 may be transmitted to the first auxiliary node F1 through the first auxiliary transistor M9. When the first auxiliary control signal fc1 at the first auxiliary control terminal VFC1 is at an inactive logic low level, the first auxiliary control signal fc1 may control the first auxiliary transistor M9 to turn off. In this case, the active logic high level of the third level signal from the third level terminal VG3 cannot be transmitted to the first auxiliary node F1 through the first auxiliary transistor M9.

In an optional embodiment, with continued reference to FIG. 23, the third level terminal VG3 is reused as the first level terminal VG1, and the first auxiliary control terminal VFC1 is reused as the first node Q1.

Illustratively, an example in which the active levels are all logic high levels and the inactive levels are all logic low levels is used. With reference to FIG. 12 and FIG. 23, during a period in which the input signal vin at the signal input terminal VIN is at an inactive level and the first clock signal ck1 at the first clock terminal VCK1 is at an active logic high level, for example, during the periods t0 and t3, the first input unit 111 is turned on. The signal at the first node Q1 is consistent with the input signal vin at the signal input terminal VIN. When the signal at the first node Q1 is at an inactive logic low level, the first auxiliary transistor M9 is turned off. In this case, the first node Q1 can be stably maintained at an inactive logic low level and is not affected by the active logic high level of the third level signal from the third level terminal VG3, so as to reset the first node Q1 and the second node Q2. During the second period t2 in which the input signal vin is at an inactive level and the first node Q1 and the second node Q2 are at an active level, the active logic high level at the first node Q1 may control the first auxiliary transistor M9 to turn on so that the active logic high level of the third level signal from the third level terminal VG3 is transmitted to the first node Q1, maintaining the stability of the signals at the first node Q1 and the second node Q2. Thus, the third level terminal VG3 is configured to be reused as the first level terminal VG1 and the first auxiliary control terminal VFC1 is configured to be reused as the first node Q1 so that the circuit structure of the shift register 101 can be simplified on the basis of achieving the stability of the signals at the first node Q1 and the second node Q2 and the reliability of the reset.

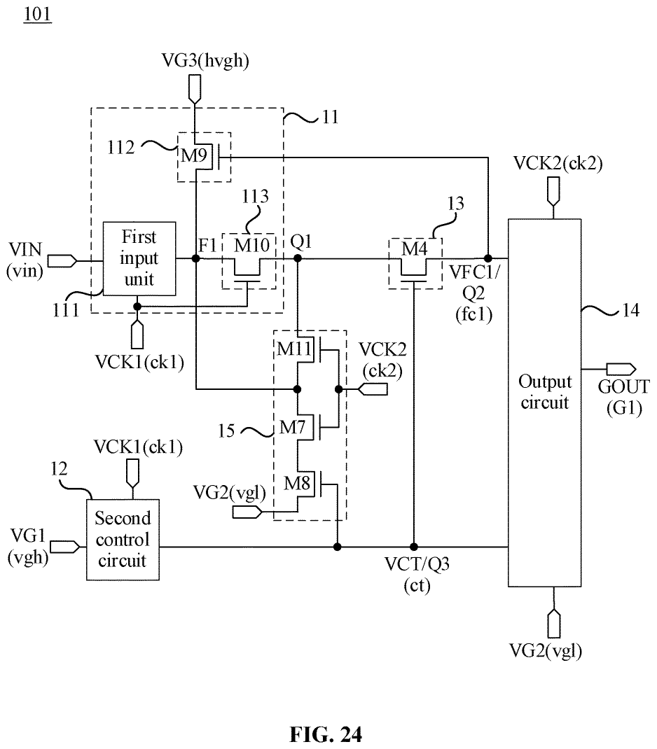

In another optional embodiment, FIG. 24 is a thirteenth schematic diagram illustrating the circuit structure of a shift register according to an embodiment of the present disclosure. As shown in FIG. 24, the voltage at the third level terminal VG3 has the same polarity as the voltage at the first level terminal VG1, and the absolute value of the voltage at the third level terminal VG3 is greater than the absolute value of the voltage at the first level terminal VG1. The first auxiliary control terminal VFC1 is reused as the second node Q2. During at least part of a period in which a signal at the first node Q1 and a signal at the second node Q2 are both at an active level, the absolute value of the voltage of the signal at the second node Q2 is greater than the absolute value of the voltage of the signal at the first node Q1.

Illustratively, an example in which the active levels are all logic high levels and the inactive levels are all logic low levels is used. With reference to FIG. 15 and FIG. 24, the first level signal at the first level terminal VG1 may be a normal high-level signal vgh, and the third level signal at the third level terminal VG3 may be an enhanced high-level signal hvgh. The voltage of the enhanced high-level signal hvgh is greater than the voltage of the normal high-level signal vgh. When the active level at the second node Q2 controls the first auxiliary transistor M9 to turn on, the potential transmitted to the first auxiliary node F1 is higher, which can reduce the leakage current transmitted from the first node Q1 to the first auxiliary node F1 through the second input transistor M10 and the leakage current transmitted from the first node Q1 to the first auxiliary node F1 through the third reset transistor M11. This configuration contributes to improving the stability of the signal at the first node Q1, thereby reducing the leakage current between the first node Q1 and the second node Q2 and further improving the stability of the signal at the second node Q2.

During the second period t2, the signals at the first node Q1 and the second node Q2 are both at an active logic high level. During at least part of the second period t2, the voltage of the signal at the second node Q2 is greater than the voltage of the signal at the first node Q1. In this case, the high-voltage signal at the second node Q2 controls the first auxiliary transistor M9 to turn on, and the first auxiliary node F1 receives the enhanced high-level signal hvgh from the third level terminal VG3. At this time, the second clock signal ck2 is also at an active logic high level. The voltage difference between the second clock signal ck2 and the first auxiliary node F1 is less than zero, that is, the voltage difference between the gate and the second electrode of the third reset transistor M11 is less than the threshold voltage of the third reset transistor M11 (the threshold voltage of an N-type transistor is greater than zero). In this manner, the third reset transistor M11 is caused to be completely turned off, preventing the signal at the first node Q1 from leaking to the second level terminal VG2 through the third reset transistor M11, and further improving the accuracy of the signals at the first node Q1 and the second node Q2.

It is to be noted that for illustration, the preceding description only uses the example in which the third level terminal VG3 is reused as the first level terminal VG1 and the first auxiliary control terminal VFC1 is reused as the first node Q1, and the example in which the voltage at the third level terminal VG3 has the same polarity as the voltage at the first level terminal VG1, the absolute value of the voltage at the third level terminal VG3 is greater than the absolute value of the voltage at the first level terminal VG1, and the first auxiliary control terminal VFC1 is reused as the second node Q2. In other optional embodiments, it is possible that the third level terminal VG3 of the shift register 101 is reused as the first level terminal VG1, and the first auxiliary control terminal VFC1 is reused as the second node Q2; or it is possible that the voltage at the third level terminal VG3 has the same polarity as the voltage at the first level terminal VG1, the absolute value of the voltage at the third level terminal VG3 is greater than the absolute value of the voltage at the first level terminal VG1, and the first auxiliary control terminal VFC1 is reused as the first node Q1. The circuit structure of the shift register 101 may be set according to actual needs, and no limitation is imposed by the embodiments of the present disclosure.

It can be understood that when the first control circuit 11 includes the third level terminal VG3 and the first auxiliary control terminal VFC1, the specific structure of the isolation control circuit 13 may be set according to actual needs. In an embodiment, with reference to FIG. 10, FIG. 13, FIG. 14, FIG. 16, and FIG. 18 to FIG. 24, the isolation control circuit 13 may include an isolation control transistor M4. The isolation control transistor M4 may be turned off during at least part of a period in which the signal at the second node Q2 is at an active level and the input signal vin at the signal input terminal VIN is at an inactive level. The relevant timing may refer to the preceding description and will not be repeated here. In another embodiment, the gate of the isolation control transistor M4 may also receive a fixed level signal so that the isolation control transistor M4 is always in an on state. The connection relationship and timing of the isolation control transistor M4 are not limited in the embodiment of the present disclosure.

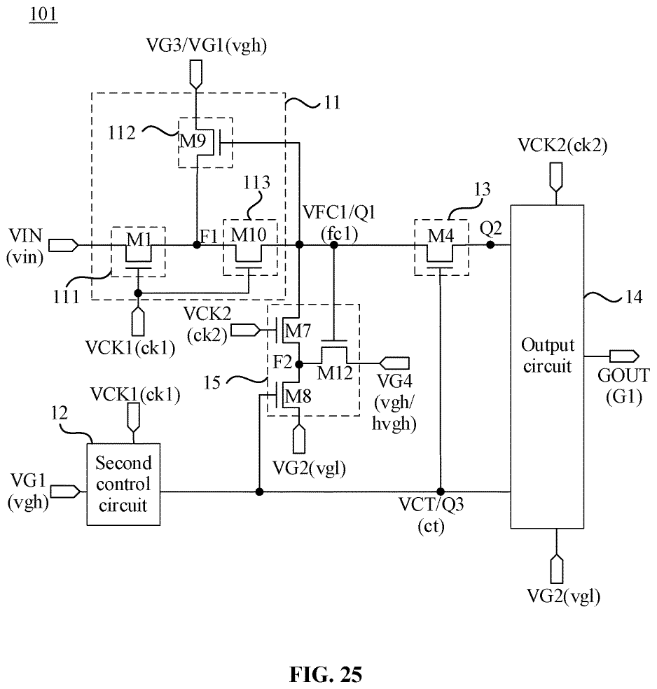

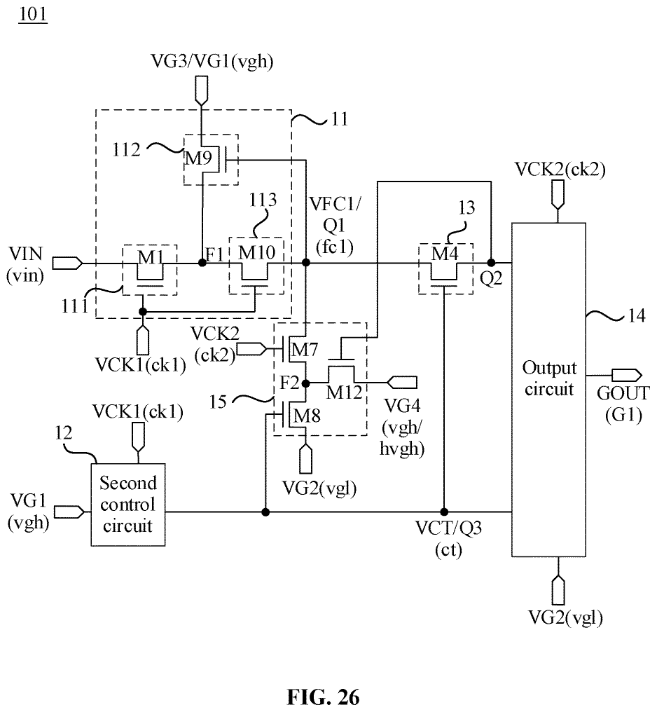

Optionally, FIG. 25 is a fourteenth schematic diagram illustrating the circuit structure of a shift register according to an embodiment of the present disclosure, and FIG. 26 is a fifteenth schematic diagram illustrating the circuit structure of a shift register according to an embodiment of the present disclosure. With reference to FIG. 25 and FIG. 26, the shift register 101 also includes a first reset circuit 15 and a fourth level terminal VG4. The first reset circuit 15 includes a first reset transistor M7, a second reset transistor M8, and a second auxiliary transistor M12. A first electrode of the first reset transistor M7 is electrically connected to the first node Q1. A second electrode of the first reset transistor M7 and a first electrode of the second reset transistor M8 are electrically connected to a second auxiliary node F2. A gate of the first reset transistor M7 is electrically connected to the second clock terminal VCK2. A second electrode of the second reset transistor M8 is electrically connected to the second level terminal VG2, and a gate of the second reset transistor M8 is electrically connected to the third node Q3. A first electrode of the second auxiliary transistor M12 is electrically connected to the fourth level terminal VG4. A second electrode of the second auxiliary transistor M12 is electrically connected to the second auxiliary node F2. A gate of the second auxiliary transistor M12 is electrically connected to the first node Q1 or the second node Q2.

The fourth level terminal VG4 may receive a fourth level signal. The fourth level signal may be a fixed level. The fixed level may be the active level of the first node Q1.

Illustratively, an example in which the active levels are all logic high levels and the inactive levels are all logic low levels is used. With reference to FIG. 12, FIG. 25, and FIG. 26, the first reset transistor M7, the second reset transistor M8, and the second auxiliary transistor M12 are all N-type transistors. During the second period t2 in which the signals at the first node Q1 and the second node Q2 are both at an active level and the input signal vin at the signal input terminal VIN and the first clock signal ck1 are both at an inactive level, the signals at the first node Q1 and the second node Q2 are both at an active logic high level. The active logic high level at the first node Q1 or the second node Q2 may control the second auxiliary transistor M12 to turn on. The active logic high level of the fourth level signal from the fourth level terminal VG4 may be transmitted to the second auxiliary node F2 through the second auxiliary transistor M12 so that the signal at the second electrode of the first reset transistor M7 is the active logic high level of the fourth level signal. This configuration contributes to reducing the leakage current transmitted from the signal at the first node Q1 to the second auxiliary node F2 through the first reset transistor M7 and maintaining the stability of the signals at the first node Q1 and the second node Q2.

It can be understood that the first reset transistor M7, the second reset transistor M8, and the second auxiliary transistor M12 may also be P-type transistors. In this case, the active level is a logic low level, and the inactive level is a logic high level. The principle is the same, which is not repeated in the embodiment of the present disclosure.

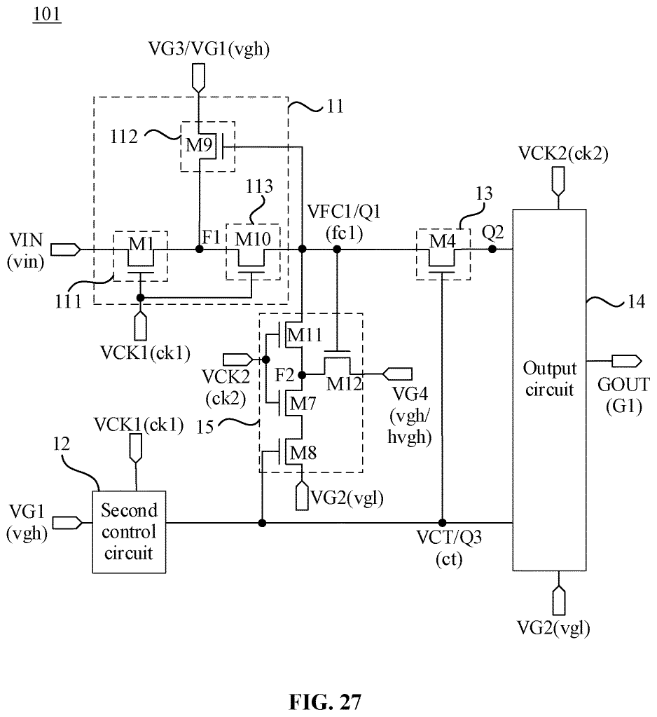

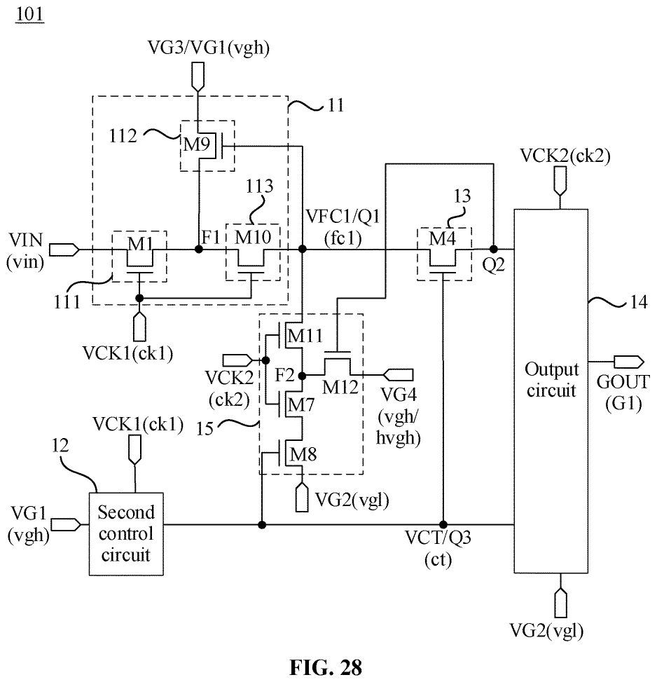

Optionally, FIG. 27 is a sixteenth schematic diagram illustrating the circuit structure of a shift register according to an embodiment of the present disclosure, and FIG. 28 is a seventeenth schematic diagram illustrating the circuit structure of a shift register according to an embodiment of the present disclosure. As shown in FIG. 27 and FIG. 28, the shift register 101 also includes a first reset circuit 15 and a fourth level terminal VG4. The first reset circuit 15 includes a first reset transistor M7, a second reset transistor M8, a third reset transistor M11, and a second auxiliary transistor M12. A first electrode of the third reset transistor M11 is electrically connected to the first node Q1. A second electrode of the third reset transistor M11 and a first electrode of the first reset transistor M7 are electrically connected to a second auxiliary node F2. A gate of the third reset transistor M11 and a gate of the first reset transistor M7 are both electrically connected to the second clock terminal VCK2. A second electrode of the first reset transistor M7 is electrically connected to a first electrode of the second reset transistor M8. A second electrode of the second reset transistor M8 is electrically connected to the second level terminal VG2, and a gate of the second reset transistor M8 is electrically connected to the third node Q3. A first electrode of the second auxiliary transistor M12 is electrically connected to the fourth level terminal VG4. A second electrode of the second auxiliary transistor M12 is electrically connected to the second auxiliary node F2. A gate of the second auxiliary transistor M12 is electrically connected to the first node Q1 or the second node Q2.

Specifically, the first reset circuit 15 is provided so that when the signals at the first node Q1 and the second node Q2 are both at an active level, the active level at the first node Q1 or the second node Q2 may control the second auxiliary transistor M12 to turn on. The active level of the fourth level signal from the fourth level terminal VG4 may be transmitted to the second auxiliary node F2 through the second auxiliary transistor M12 so that the signal at the second electrode of the third reset transistor M11 is at an active level. This configuration contributes to reducing the leakage current transmitted from the signal at the first node Q1 to the second auxiliary node F2 through the third reset transistor M11, further reducing the leakage current between the first node Q1 and the second level terminal VG2, and maintaining the stability of the signals at the first node Q1 and the second node Q2.

On the basis of the preceding embodiments, the fourth level terminal VG4 may be reused as the first level terminal VG1. In this manner, the number of signal lines provided in the shift register 101 can be reduced, and the circuit structure of the shift register 101 can be simplified. Illustratively, when the active levels are all logic high levels and the inactive levels are all logic low levels, the first electrode of the second auxiliary transistor M12 may receive a normal high-level signal vgh.

On the basis of the preceding embodiments, the voltage at the fourth level terminal VG4 has the same polarity as the voltage at the first level terminal VG1, and the absolute value of the voltage at the fourth level terminal VG4 is greater than the absolute value of the voltage at the first level terminal VG1. Illustratively, when the active levels are all logic high levels and the inactive levels are all logic low levels, the first electrode of the second auxiliary transistor M12 may receive an enhanced high-level signal hvgh. The voltage of the enhanced high-level signal hvgh is greater than the voltage of the normal high-level signal vgh, which contributes to further reducing the leakage current of the signal at the first node Q1 flowing through the first reset transistor M7 and improving the stability of the signals at the first node Q1 and the second node Q2.

It can be understood that when the shift register 101 includes the first reset circuit 15 and the fourth level terminal VG4, the specific structure of the first control circuit 11 may be set according to actual needs. In an optional embodiment, with reference to FIG. 25 to FIG. 28, the first control circuit 11 includes a first input unit 111, a first auxiliary unit 112, and a second input unit 113. The connection relationships and the related timing of the first input unit 111, the first auxiliary unit 112, and the second input unit 113 may refer to the preceding description and will not be repeated here. The gate of the first auxiliary unit 112 may be electrically connected to the gate of the second auxiliary transistor M12 at the same node to receive the same signal, or the gate of the first auxiliary unit 112 may also be electrically connected to the gate of the second auxiliary transistor M12 at different nodes to receive different signals. The third level terminal VG3 may be reused as the fourth level terminal VG4, or the third level terminal VG3 may not be reused as the fourth level terminal VG4. The connection relationships and the timing of the first input unit 111, the first auxiliary unit 112, and the second input unit 113 are not limited in the embodiment of the present disclosure.

On the basis of the preceding embodiments, the second auxiliary transistor M12 may be reused as the first auxiliary transistor M9, and the second auxiliary node F2 is electrically connected to the first auxiliary node F1 (not shown in FIG. 25 to FIG. 28), which contributes to simplifying the circuit structure of the shift register 101.

In another optional embodiment, the first control circuit 11 may also include only the first input unit 111 (not shown in FIG. 25 to FIG. 28). Whether the first control circuit 11 includes only the first input unit 111 or includes the first input unit 111 and other circuit units, the first input unit 111 may include a first input transistor M1. A first electrode of the first input transistor M1 is electrically connected to the signal input terminal VIN, a second electrode of the first input transistor M1 is coupled to the first node Q1, and a gate of the first input transistor M1 is electrically connected to the first clock terminal VCK1.

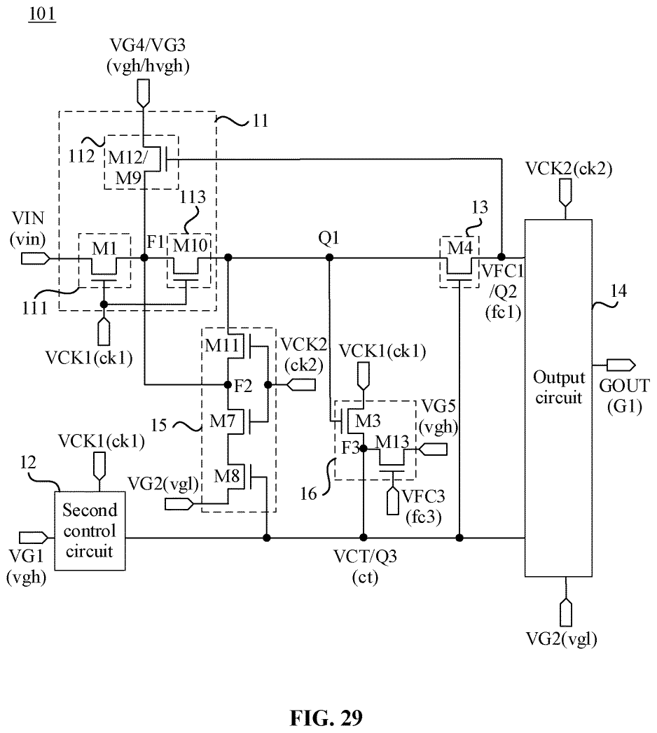

Optionally, FIG. 29 is an eighteenth schematic diagram illustrating the circuit structure of a shift register according to an embodiment of the present disclosure. As shown in FIG. 29, the shift register 101 also includes a second reset circuit 16, a fifth level terminal VG5, and a third auxiliary control terminal VFC3. The second reset circuit 16 includes a fourth reset transistor M3 and a third auxiliary transistor M13. A first electrode of the fourth reset transistor M3 is electrically connected to the first clock terminal VCK1. A second electrode of the fourth reset transistor M3 is coupled to the third node Q3. A gate of the fourth reset transistor M3 is electrically connected to the first node Q1. A first electrode of the third auxiliary transistor M13 is electrically connected to the fifth level terminal VG5. A second electrode of the third auxiliary transistor M13 and a second electrode of the fourth reset transistor M3 are electrically connected to a third auxiliary node F3. A gate of the third auxiliary transistor M13 is electrically connected to the third auxiliary control terminal VFC3.

In the same shift register 101, during at least part of a period in which the gate driving signal G1 at the signal output terminal GOUT is at an inactive level, a third auxiliary control signal fc3 at the third auxiliary control terminal VFC3 controls the third auxiliary transistor M13 to establish a signal transmission path between the fifth level terminal VG5 and the third auxiliary node F3.

The fifth level terminal VG5 may receive a fifth level signal. The fifth level signal may be a fixed level. The fixed level may be the active level of the third node Q3. When the active level of the third node Q3 is a logic high level, the fifth level signal may be a logic high-level signal vgh. When the active level of the third node Q3 is a logic low level, the fifth level signal may be a logic low-level signal vgl. The third auxiliary control terminal VFC3 may receive a varying third auxiliary control signal fc3 to control the third auxiliary transistor M13 to be in an on or off state under the action of different levels of the third auxiliary control signal fc3.

Specifically, the third auxiliary signal fc3 at the third auxiliary control terminal VFC3 may control the third auxiliary transistor M13 to establish or disconnect the signal transmission path between the fifth level terminal VG5 and the third auxiliary node F3. When the third auxiliary signal fc3 at the third auxiliary control terminal VFC3 controls the third auxiliary transistor M13 to turn on, the fifth level signal from the fifth level terminal VG5 may be transmitted to the third auxiliary node F3 through the third auxiliary transistor M13. Since the third auxiliary node F3 is coupled to the third node Q3 (it is possible that the third auxiliary node F3 is directly electrically connected to the third node Q3, or the third auxiliary node F3 is indirectly electrically connected to the third node Q3), the third auxiliary node F3 may transmit the fifth level signal to the third node Q3 so that the signal at the third node Q3 is maintained at the fifth level signal. Thus, during at least part of a period in which the gate driving signal G1 is at an inactive level, the active level of the fifth level signal from the fifth level terminal VG5 is written to the third auxiliary node F3. This configuration contributes to improving the stability of the signal at the third node Q3 so that the output circuit 14 can stably output the inactive level signal from the second level terminal VG2 under the action of the active level at the third node Q3, thereby improving the stability of the gate driving signal G1 output from the signal output terminal GOUT when the gate driving signal G1 is at an inactive level. When the third auxiliary signal fc3 at the third auxiliary control terminal VFC3 controls the third auxiliary transistor M13 to disconnect the signal transmission path between the fifth level terminal VG5 and the third auxiliary node F3, the fifth level signal from the fifth level terminal VG5 cannot be transmitted to the third auxiliary node F3 through the third auxiliary transistor M13. In this case, if the fourth reset transistor M3 is turned on, the first clock signal ck1 may be transmitted to the third node Q3 through the fourth reset transistor M3. For example, when the signal at the first node Q1 is at an inactive level and the first clock signal ck1 is also at an inactive level, the third node Q3 may be reset to an inactive level through the fourth reset transistor M3. In an embodiment, during at least part of a period in which the signal at the first node Q1 and the first clock signal ck1 at the first clock terminal VCK1 are both at an inactive level, the third auxiliary control signal fc3 at the third auxiliary control terminal VFC3 controls the third auxiliary transistor M13 to establish the signal transmission path between the fifth level terminal VG5 and the third auxiliary node F3. In this manner, when the signal at the first node Q1 is at an inactive level, the leakage current generated from the inactive level of the first clock signal ck1 to the third auxiliary node F3 can be reduced, and the stability of the signal at the third node Q3 can be improved, thereby improving the stability of the gate driving signal G1 when the gate driving signal G1 is at an inactive level.

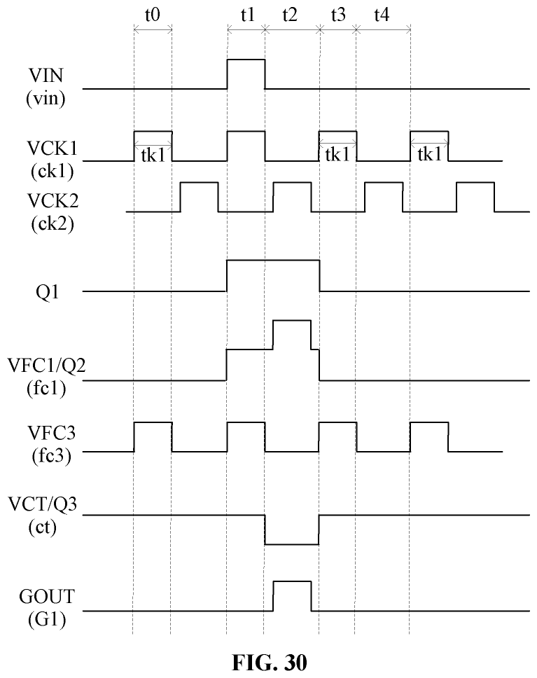

Illustratively, an example in which the active levels are all logic high levels and the inactive levels are all logic low levels is used. FIG. 30 is a ninth timing graph of a shift register according to an embodiment of the present disclosure. As shown in FIG. 29 and FIG. 30, during at least part of a period in which the gate driving signal G1 at the signal output terminal GOUT is at an inactive logic low level, the third auxiliary control signal fc3 at the third auxiliary control terminal VFC3 is at an active logic high level to control the third auxiliary transistor M13 to establish the signal transmission path between the fifth level terminal VG5 and the third auxiliary node F3. It can be understood that at least part of a period in which the gate driving signal G1 at the signal output terminal GOUT is at an inactive logic low level may be a part of the period or the entire period in which the gate driving signal G1 is at an inactive logic low level. The third auxiliary control signal fc3 at the third auxiliary control terminal VFC3 controls the third auxiliary transistor M13 to turn on. The active logic high level of the fifth level signal from the fifth level terminal VG5 may be transmitted to the third auxiliary node F3 through the third auxiliary transistor M13 so that the signal at the third node Q3 is maintained at an active logic high level. In addition, this configuration contributes to reducing the leakage current transmitted from the first clock terminal VCK1 to the third node Q3 through the fourth reset transistor M3 and improving the stability of the signal at the third node Q3 so that the output circuit 14 can stably output the inactive logic low level signal from the second level terminal VG2 under the action of the active logic high level at the third node Q3, thereby improving the stability of the gate driving signal output from the signal output terminal GOUT.

The fifth level signal at the fifth level terminal VG5 may have the same polarity as the first level signal provided by the first level terminal VG1. The absolute value of the voltage of the fifth level signal may be the same as the absolute value of the voltage of the first level signal, or the absolute value of the voltage of the fifth level signal may be greater than the absolute value of the voltage of the first level signal, which may be set according to actual needs. When the fifth level signal has the same polarity as the first level signal, and the absolute value of the voltage of the fifth level signal is consistent with the absolute value of the voltage of the first level signal, the fifth level terminal VG5 may be configured to be reused as the first level terminal VG1 to simplify the overall structure of the shift register 101.

On the basis of the preceding embodiments, with continued reference to FIG. 29 and FIG. 30, in the same shift register 101, when the gate driving signal G1 at the signal output terminal GOUT is at an active level, the third auxiliary control signal fc3 at the third auxiliary control terminal VFC3 controls the third auxiliary transistor M13 to disconnect the signal transmission path between the fifth level terminal VG5 and the third auxiliary node F3.

Illustratively, an example in which the active levels are all logic high levels and the inactive levels are all logic low levels is used. With reference to FIG. 29 and FIG. 30, during a period tg in which the gate driving signal G1 at the signal output terminal GOUT is at an active logic high level, the third auxiliary control signal fc3 is at an inactive logic low level. The inactive logic low level of the third auxiliary control signal fc3 controls the third auxiliary transistor M13 to disconnect the signal transmission path between the fifth level terminal VG5 and the third auxiliary node F3 so that the active logic high level of the fifth level signal from the fifth level terminal VG5 cannot be transmitted to the third auxiliary node F3. In this case, the third node Q3 is not affected by the fifth level signal. At the same time, the first node Q1 is at an active logic high level, and the first clock signal ck1 is at an inactive logic low level. The fourth reset transistor M3 is turned on and may transmit the inactive logic low level of the first clock signal ck1 to the third node Q3 so that the signal at the third node Q3 can be reset to an inactive logic low level and stably maintained at an inactive logic low level. Under the action of the active level at the second node Q2 and the inactive level at the third node Q3, the output circuit 14 may output the active level of the second clock signal ck2 as the active level of the gate driving signal G1, improving the accuracy of the gate driving signal G1.

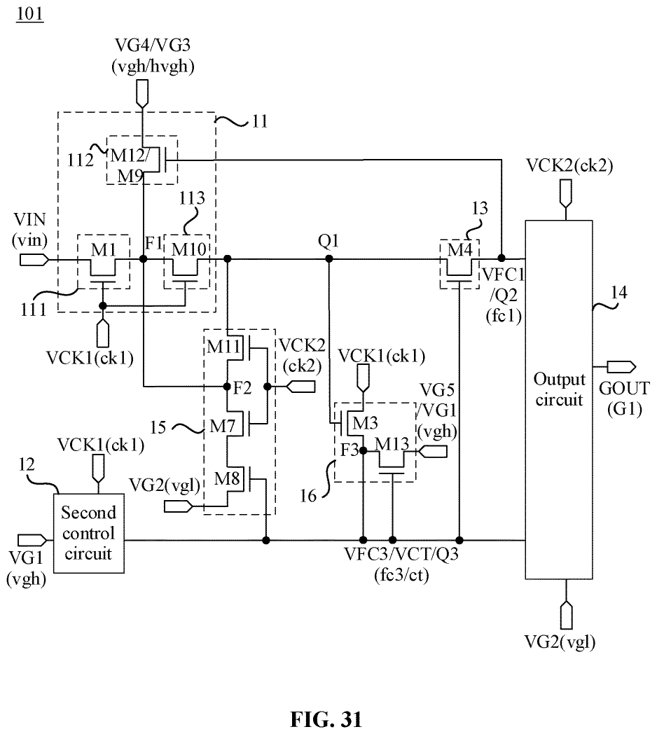

Optionally, FIG. 31 is a nineteenth schematic diagram illustrating the circuit structure of a shift register according to an embodiment of the present disclosure. As shown in FIG. 31, the third auxiliary control terminal VFC3 is reused as the third node Q3.

Illustratively, an example in which the active levels are all logic high levels and the inactive levels are all logic low levels is used. With reference to FIG. 30 and FIG. 31, before and after the period tg in which the gate driving signal G1 is at an active logic high level, the signal at the third node Q3 includes an active logic high level, that is, the third auxiliary control signal fc3 also includes an active logic high level and may control the third auxiliary transistor M13 to turn on. The active logic high level of the fifth level signal from the fifth level terminal VG5 may be transmitted to the third node Q3 so that the third node Q3 is maintained at an active logic high level. Under the action of the active logic high level at the third node Q3, the output circuit 14 may transmit the inactive logic low level of the second level signal from the second level terminal VG2 to the signal output terminal GOUT. During the period tg in which the gate driving signal G1 is at an active logic high level, the signal at the third node Q3 is at an inactive logic low level, that is, the third auxiliary control signal fc3 is also at an inactive logic low level and may control the third auxiliary transistor M13 to disconnect the signal transmission path between the fifth level terminal VG5 and the third auxiliary node F3. The active logic high level of the fifth level signal from the fifth level terminal VG5 cannot be transmitted to the third node Q3 so that the third node Q3 is maintained at an inactive logic low level. Under the action of the inactive logic low level at the third node Q3 and the active logic high level at the second node Q2, the output circuit 14 may transmit the active logic high level of the second clock signal ck2 from the second clock terminal VCK2 to the signal output terminal GOUT, improving the accuracy of the gate driving signal G1. Thus, the third auxiliary control terminal VFC3 is configured to be reused as the third node Q3 so that the output circuit 14 can output an accurate gate driving signal G1 without separately setting a control circuit or signal line for providing the third auxiliary control signal fc3 at the third auxiliary control terminal VFC3. Moreover, the circuit structure of the shift register 101 can be simplified.

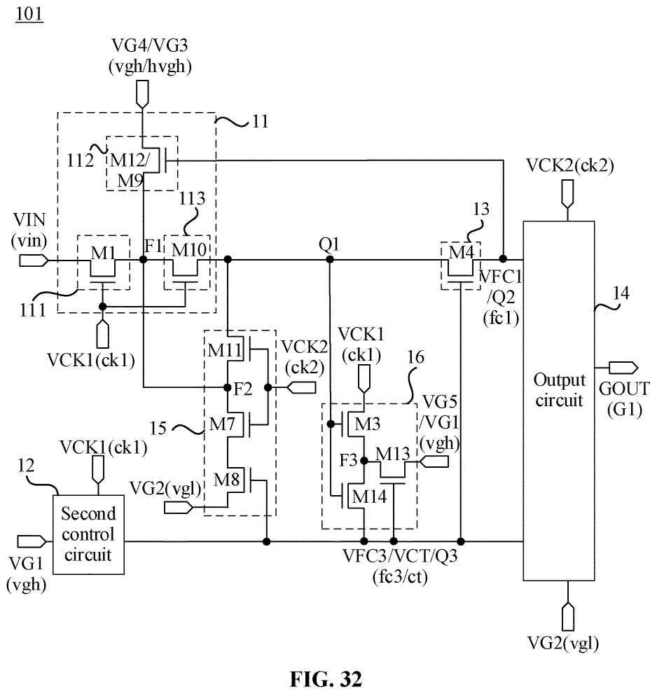

It can be understood that the preceding description only uses the example in which the first auxiliary node F3 is directly electrically connected to the first node Q3 for illustration. In other optional embodiments, the third auxiliary node F3 may also be electrically connected to the third node Q3 through an intermediate circuit. In an optional embodiment, FIG. 32 is a twentieth schematic diagram illustrating the circuit structure of a shift register according to an embodiment of the present disclosure. As shown in FIG. 32, the second reset circuit 16 also includes a fifth reset transistor M14. A first electrode of the fifth reset transistor M14 and the second electrode of the fourth reset transistor M3 are electrically connected to the third auxiliary node F3. A second electrode of the fifth reset transistor M14 is electrically connected to the third node Q3. A gate of the fifth reset transistor M14 is electrically connected to the first node Q1.

Illustratively, an example in which the active levels are all logic high levels and the inactive levels are all logic low levels is used. With reference to FIG. 30 and FIG. 32, the fourth reset transistor M3, the third auxiliary transistor M13, and the fifth reset transistor M14 are all N-type transistors. When the signal at the third node Q3 is at an active logic high level and the signals at the first node Q1 and the first clock terminal VCK1 are both at an inactive logic low level, for example, during a period t4, the third node Q3 may control the third auxiliary transistor M13 to turn on. The active logic high level of the fifth level signal from the fifth level terminal VG5 may be transmitted to the third auxiliary node F3 so that the third auxiliary node F3 is maintained at an active logic high level. The gate of the fifth reset transistor M14 receives the inactive logic low level at the first node Q1. The first electrode and the second electrode of the fifth reset transistor M14 receive the active levels at the third node Q3 and the third auxiliary node F3, respectively, so that the voltage differences between the gate and the first electrode and between the gate and the second electrode of the fifth reset transistor M14 are both less than zero. In this manner, the voltage differences between the gate and the first electrode and between the gate and the second electrode of the fifth reset transistor M14 are both less than the threshold voltage of the fifth reset transistor M14 (the threshold voltage of an N-type transistor is greater than zero). The fifth reset transistor M14 is in a completely off state, which can reduce the leakage current between the third node Q3 and the first clock terminal VCK1 and enable the third node Q3 to stably remain at an active logic high level, thereby improving the stability of the signal at the third node Q3.

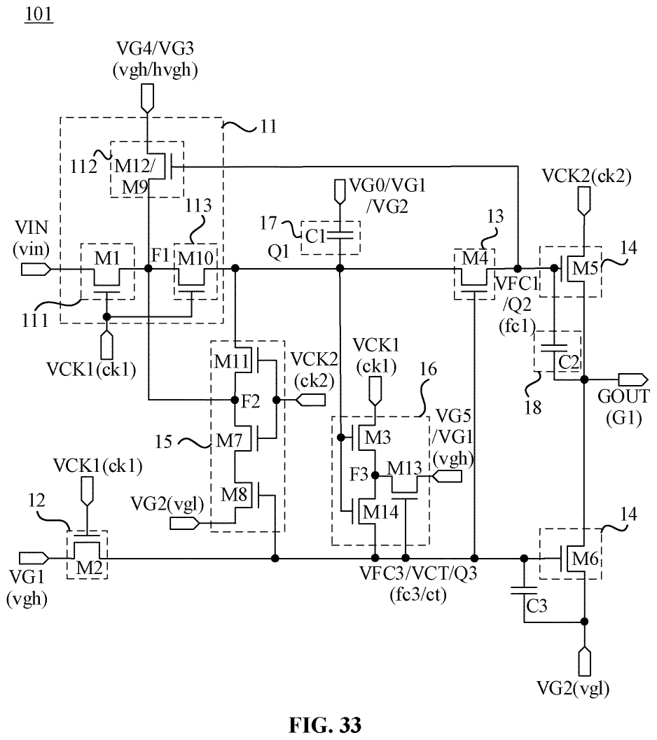

Optionally, FIG. 33 is a twenty-first schematic diagram illustrating the circuit structure of a shift register according to an embodiment of the present disclosure. As shown in FIG. 33, the shift register 101 also includes a first storage circuit 17, and the first storage circuit 17 includes a first storage capacitor C1. A first plate of the first storage capacitor C1 is electrically connected to the first node Q1, and a second plate of the first storage capacitor C1 is electrically connected to a fixed level terminal VG0.

The fixed level terminal VG0 may provide a logic low-level signal vgl or a logic high-level signal vgh. When the signal provided by the fixed level terminal VG0 is at an inactive level, the fixed level terminal VG0 may be reused as the second level terminal VG2; when the signal provided by the fixed level terminal VG0 is at an active level, the fixed level terminal VG0 may be reused as the first level terminal VG1, which may be set according to actual needs, and no limitation is imposed by the embodiments of the present disclosure.

Specifically, the second plate of the first storage capacitor C1 receives the fixed level signal from the fixed level terminal VG0. The first plate of the first storage capacitor C1 is electrically connected to the first node Q1 so that the first storage capacitor C1 can store the signal at the first node Q1 to ensure the stability of the signal at the first node Q1. Illustratively, when the first clock signal ck1 at the first clock terminal VCK1 controls the first control circuit 11 to disconnect the signal transmission path between the signal input terminal VIN and the first node Q1, and/or the isolation control signal ct at the isolation control terminal VCT controls the isolation control circuit 13 to disconnect the signal transmission path between the first node Q1 and the second node Q2, the first storage capacitor C1 can store and maintain the signal at the first node Q1 and reduce the leakage current at the first node Q1.

Optionally, with continued reference to FIG. 33, the second control circuit 12 includes a first control transistor M2. A first electrode of the first control transistor M2 is electrically connected to the first level terminal VG1. A second electrode of the first control transistor M2 is electrically connected to the third node Q3. A gate of the first control transistor M2 is electrically connected to the first clock terminal VCK1.

Specifically, the second control transistor T2 may be turned on or turned off under the control of the first clock signal ck1 at the first clock terminal VCK1. When the first clock signal ck1 controls the second control transistor T2 to turn on, a conduction path may be formed between the first level terminal VG1 and the third node Q3 so that the signal from the first level terminal VG1 is transmitted to the third node Q3, and the signal at the third node Q3 is consistent with the signal at the first level terminal VG1.

Optionally, with continued reference to FIG. 33, the output circuit 14 includes a first output transistor M5 and a second output transistor M6. In the same shift register 101, a first electrode of the first output transistor M5 is electrically connected to the second clock terminal VCK2. A second electrode of the first output transistor M5 is electrically connected to the signal output terminal GOUT. A gate of the first output transistor M5 is electrically connected to the second node Q2. A first electrode of the second output transistor M6 is electrically connected to the second level terminal VG2. A second electrode of the second output transistor M6 is electrically connected to the signal output terminal GOUT. A gate of the second output transistor M6 is electrically connected to the third node Q3.

Specifically, the signal at the second node Q2 may control the first output transistor T5 to turn on or turn off. When the signal at the second node Q2 is at an active level, the signal at the second node Q2 can control the first output transistor T5 to turn on so that the second clock signal ck2 from the second clock terminal VCK2 can be transmitted to the signal output terminal GOUT, and the gate driving signal G1 output from the signal output terminal GOUT is consistent with the second clock signal ck2. The signal at the third node Q3 may control the second output transistor T6 to turn on or turn off. When the signal at the third node Q3 is at an active level, the signal at the third node Q3 can control the second output transistor T6 to turn on so that the second level signal from the second level terminal VG2 is transmitted to the signal output terminal GOUT, and the gate driving signal G1 output from the signal output terminal GOUT is consistent with the second level signal. Thus, the signals at the second node Q2 and the third node Q3 are controlled so that the turn-on time of the first output transistor T5 and the second output transistor T6 can be controlled, thereby controlling the time of the active pulse of the gate driving signal G1 output from the signal output terminal GOUT.

Optionally, with continued reference to FIG. 33, the shift register 101 also includes a bootstrap circuit 18, and the bootstrap circuit 18 includes a bootstrap capacitor C2. A first plate of the bootstrap capacitor C2 is electrically connected to the signal output terminal GOUT, and a second plate of the bootstrap capacitor C2 is electrically connected to the second node Q2.

Specifically, the bootstrap circuit 18 may couple the variation of the gate driving signal at the signal output terminal GOUT to the gate of the first output transistor T5 when the gate driving signal at the signal output terminal GOUT changes, pulling down or raising the voltage of the gate signal of the first output transistor T5 so that the gate signal of the first output transistor T5 can have a higher driving capability, thereby accurately transmitting the second clock signal ck2 to the signal output terminal GOUT and enabling the signal output terminal GOUT to accurately output the gate driving signal.

With continued reference to FIG. 33, the shift register 101 also includes a holding capacitor C3. The holding capacitor C3 may be electrically connected between the third node Q3 and the second level terminal VG2 to hold the potential at the third node Q3 so that the signal at the third node Q3 can accurately control the output circuit 14 to output the gate driving signal.

In addition to the shift register 101 shown in the preceding description, the shift register 101 may also be implemented in other manners. Some other embodiments of the shift register 101 are described below with an example in which all transistors in the shift register 101 are N-type transistors.

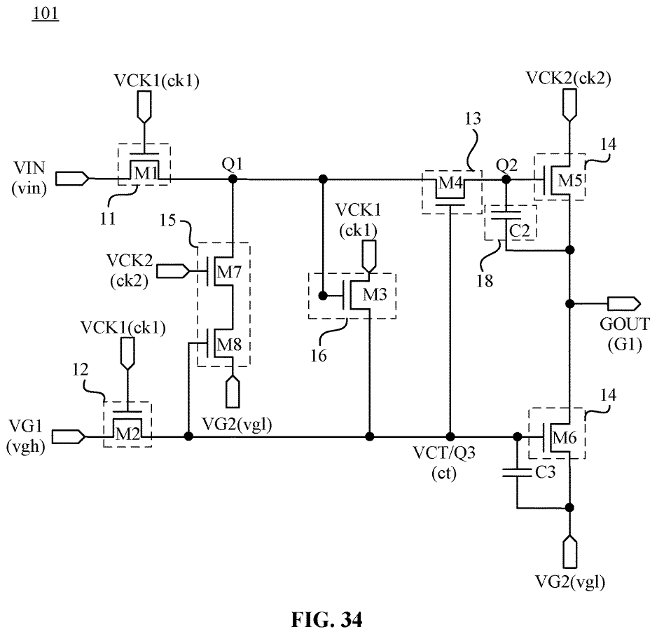

FIG. 34 is a twenty-second schematic diagram illustrating the circuit structure of a shift register according to an embodiment of the present disclosure. As shown in FIG. 34, when the gate of the isolation control transistor M4 in the isolation control circuit 13 is connected to the third node Q3, the first control circuit 11 may include only the first input transistor M1, the first reset circuit 15 may include only the first reset transistor M7 and the second reset transistor M8, and the second reset circuit 16 may include only the fourth reset transistor M3. The isolation control transistor M4 can be turned off when the signal at the third node Q3 is at an inactive level, so as to reduce the leakage current at the second node Q2, improve the stability of the signal at the second node Q2, and at the same time, reduce the number of transistors in the shift register 101 and reduce the space occupied by the shift register 101.

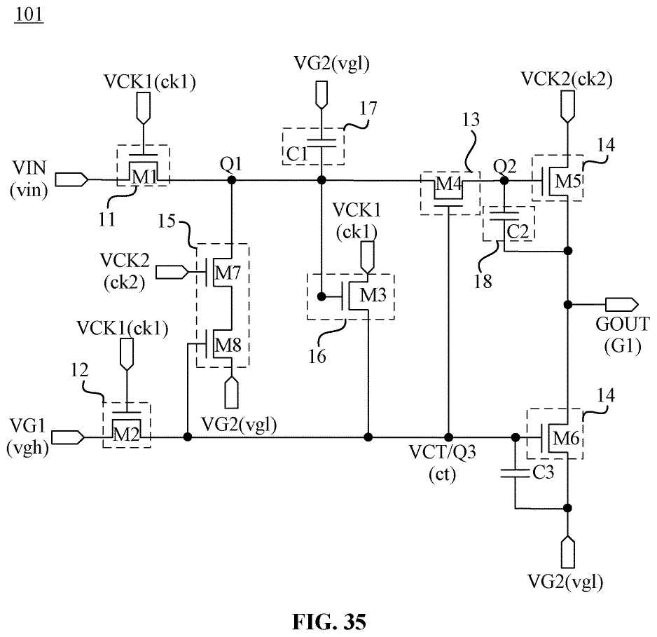

On the basis of FIG. 34, FIG. 35 is a twenty-third schematic diagram illustrating the circuit structure of a shift register according to an embodiment of the present disclosure. As shown in FIG. 35, the shift register 101 is also provided with a first storage circuit 17. The first storage capacitor C1 of the first storage circuit 17 may be connected between the first node Q1 and the second level terminal VG2. Thus, when the first input transistor M1 disconnects the signal transmission path between the signal input terminal VIN and the first node Q1, and/or the isolation control transistor M4 disconnects the transmission path between the first node Q1 and the second node Q2, the first storage capacitor C1 can store the signal at the first node Q1 to ensure the stability of the signal at the first node Q1.

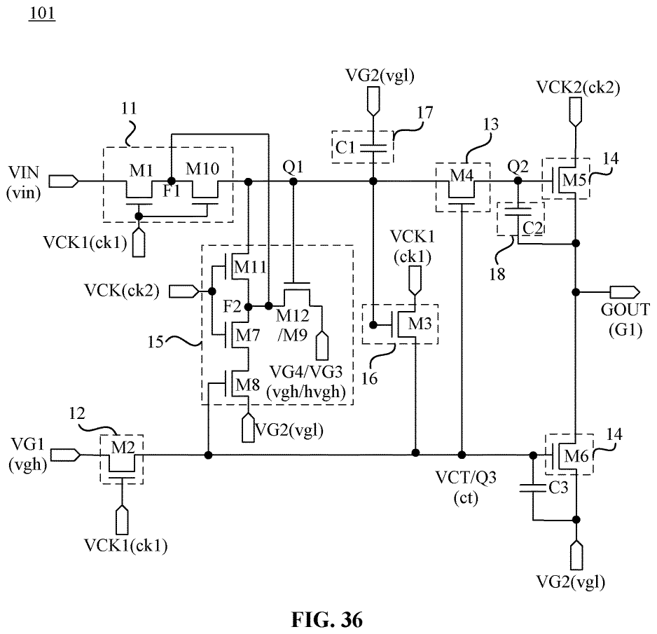

FIG. 36 is a twenty-fourth schematic diagram illustrating the circuit structure of a shift register according to an embodiment of the present disclosure As shown in FIG. 36, when the gate of the isolation control transistor M4 in the isolation control circuit 13 is connected to the third node Q3, the first control circuit 11 may also include a first input transistor M1, a first auxiliary transistor M9, and a second input transistor M10. The first reset circuit 15 may also include a first reset transistor M7, a second reset transistor M8, a third reset transistor M11, and a second auxiliary transistor M12. The second auxiliary transistor M12 may be reused as the first auxiliary transistor M9.

When the input signal vin at the signal input terminal VIN and the first clock signal ck1 both transition to an inactive logic low level, the first clock signal ck1 controls the first control circuit 11 and the second control circuit 12 to turn off, the signal at the first node Q1 is still at an active logic high level, and the active logic high level at the first node Q1 can control the second auxiliary transistor M12 to turn on. The active logic high level of the fourth level signal from the fourth level terminal VG4 may be transmitted to the second auxiliary node F2 and the first auxiliary node F1 through the second auxiliary transistor M12. This configuration contributes to reducing the leakage current transmitted from the signal at the first node Q1 to the second auxiliary node F2 through the third reset transistor M11 and the leakage current transmitted from the signal at the first node Q1 to the first auxiliary node F1 through the second input transistor M10, and maintaining the stability of the signals at the first node Q1 and the second node Q2.

On the basis of FIG. 36, with reference to FIG. 33, the second reset circuit 16 in the shift register 101 may include a fourth reset transistor M3, a third auxiliary transistor M13, and a fifth reset transistor M14 to reduce the leakage current between the third node Q3 and the first clock terminal VCK1 so that the third node Q3 is stably maintained at an active logic high level, and the stability of the signal at the third node Q3 is improved.

On the basis of FIG. 36, with continued reference to FIG. 33, in the same shift register 101, the gate of the first auxiliary transistor M9 (reused as the second auxiliary transistor M12) may also be connected to the second node Q2.

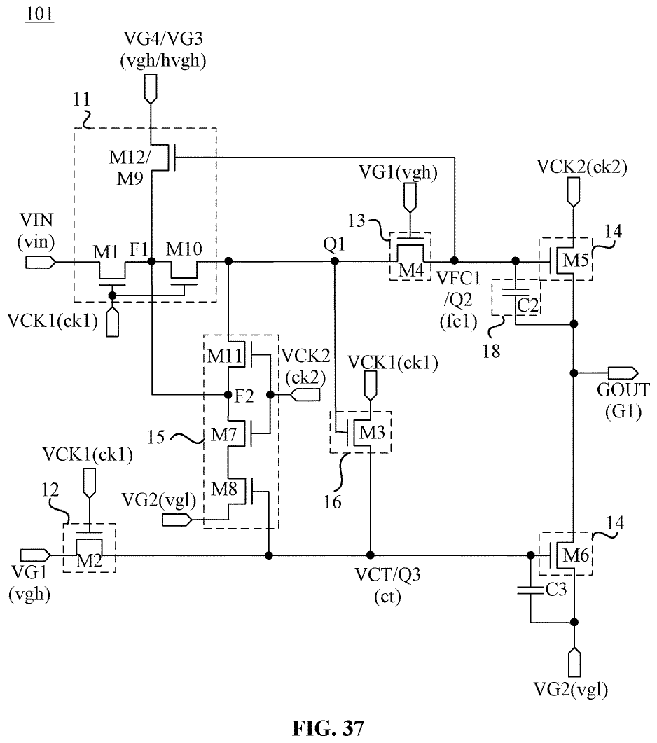

FIG. 37 is a twenty-fifth schematic diagram illustrating the circuit structure of a shift register according to an embodiment of the present disclosure. With reference to FIG. 37, when the first control circuit 11 includes a first input transistor M1, a first auxiliary transistor M9, and a second input transistor M10, and the first reset circuit 15 includes a first reset transistor M7, a second reset transistor M8, a third reset transistor M11, and a second auxiliary transistor M12 (the second auxiliary transistor M12 may be reused as the first auxiliary transistor M9), the gate of the isolation control transistor M4 may also receive a fixed level signal, for example, the logic high-level signal vgh from the first level terminal VG1 so that the isolation control transistor M4 is always in an on state. With the configuration of the first auxiliary transistor M9 and the second auxiliary transistor M12, when the first node Q1 and/or the second node Q2 is at an active logic high level, an active high-level signal can be written to the first auxiliary node F1 and the second auxiliary node F2, reducing the leakage current between the first node Q1 and the signal input terminal VIN so that the first node Q1 is stably maintained at an active logic high level. This configuration contributes to improving the stability of the signal at the second node Q2 when the signal at the second node Q2 is at an active logic high level.

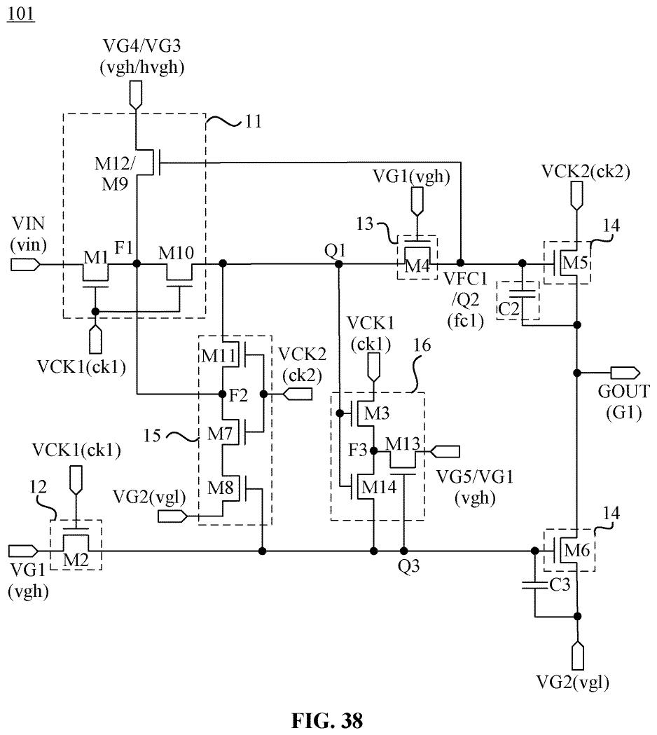

On the basis of FIG. 37, FIG. 38 is a twenty-sixth schematic diagram illustrating the circuit structure of a shift register according to an embodiment of the present disclosure. As shown in FIG. 38, the second reset circuit 16 in the shift register 101 may include a fourth reset transistor M3, a third auxiliary transistor M13, and a fifth reset transistor M14 so that an active high-level signal can be written to the third auxiliary node F3 when the third node Q3 is at an active logic high level, so as to reduce the leakage current between the third node Q3 and the first clock terminal VCK1, enable the third node Q3 to stably remain at an active logic high level, and improve the stability of the signal at the third node Q3.

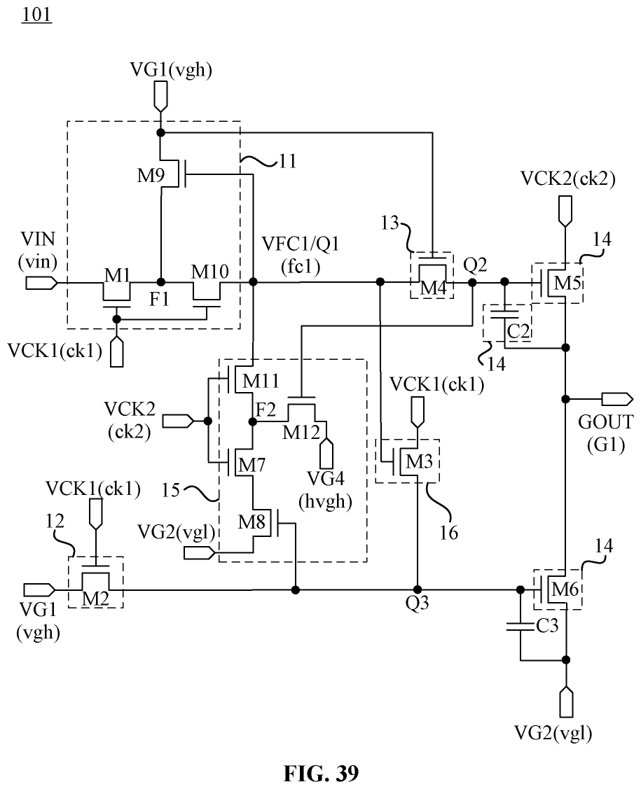

FIG. 39 is a twenty-seventh schematic diagram illustrating the circuit structure of a shift register according to an embodiment of the present disclosure. As shown in FIG. 39, the first electrode of the first auxiliary transistor M9 and the gate of the isolation control transistor M4 may both be electrically connected to the first level terminal VG1 to receive a normal logic high-level signal vgh. In this case, the gate of the first auxiliary transistor M9 may receive the signal at the first node Q1. The first electrode of the second auxiliary transistor M12 may receive the enhanced high-level signal hvgh from the fourth level terminal VG4. In this case, the gate of the second auxiliary transistor M12 may receive the signal at the second node Q2. The first auxiliary transistor M9 and the second auxiliary transistor M12 are provided independently so that the stability of the signal at the first node Q1 can be improved, preventing the signal at the first node Q1 from leaking through the first input transistor M1 and the second input transistor M10, or leaking through the first reset transistor M7, the second reset transistor M8, and the third reset transistor M11.

The gate of the first auxiliary transistor M9 in FIG. 39 may also receive the signal at the second node Q2 (not shown in FIG. 39). In this case, the gate of the first auxiliary transistor M9 and the gate of the second auxiliary transistor M12 are both electrically connected to the second node Q2.

It can be understood that the preceding description only illustratively shows some embodiments of the shift register. The circuit structure of the shift register provided by the present disclosure is not limited to the preceding structures. Different embodiments of the shift register, if not in collision, can be combined with each other.

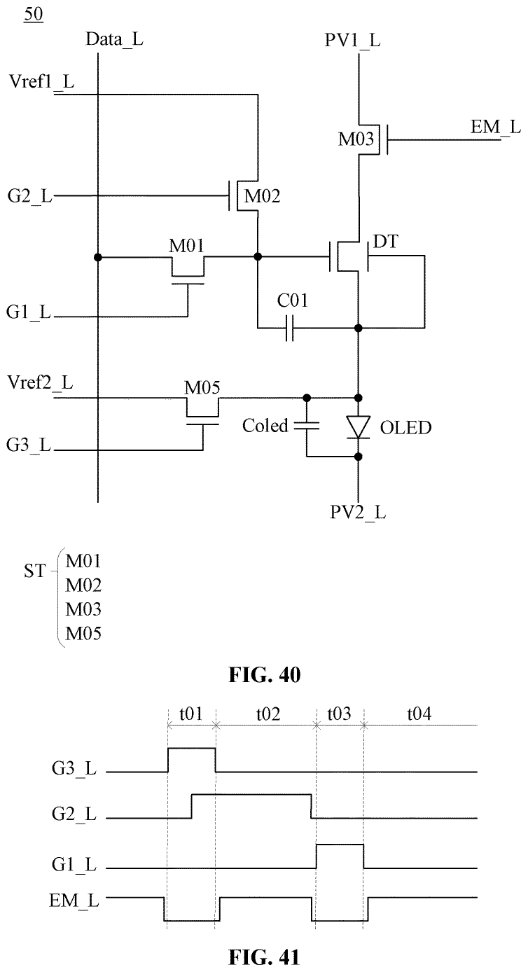

The gate driving signal G1 output by the shift register provided by the embodiment of the present disclosure may be used to drive the pixel circuit 50. Optionally, FIG. 40 is a schematic diagram illustrating the structure of a pixel circuit according to an embodiment of the present disclosure. As shown in FIG. 40, the pixel circuit 50 includes a drive transistor DT and at least one switch transistor ST. A gate of the switch transistor ST is electrically connected to the signal output terminal GOUT of the shift register 101. Both the drive transistor DT and the switch transistor ST are N-type transistors.

Specifically, the gate driving signal G1 output by the shift register 101 provided by the embodiment of the present disclosure may be used to control any one or more switch transistors ST in the pixel circuit 50 to turn on or turn off so that the drive transistor DT in the pixel circuit 50 can receive a data signal and drive the light-emitting element OLED to emit light for display based on the data signal and present a corresponding display gray scale. With the improvement in the stability of the gate driving signal G1, the drive transistor DT in the pixel circuit 50 can receive an accurate data signal, improving the accuracy of the display gray scale of the light-emitting element OLED, and thereby improving the display effect of the display panel 100. With the configuration of the drive transistor DT as an N-type transistor, the carriers in the drive transistor DT are electrons, which have higher mobility and lower sensitivity to threshold voltage. This configuration can improve the hysteresis and threshold voltage drift of the drive transistor DT and reduce image sticking. With the configuration of the switch transistor ST as an N-type transistor, the carriers in the switch transistor ST are electrons, which have higher mobility. This configuration contributes to reducing the subthreshold swing of the switch transistor ST, achieving smaller leakage current and faster on/off response, and thereby achieving fast charge and discharge, as well as a higher refresh rate and resolution. When the switch transistor ST is an N-type transistor, the active level of the gate driving signal G1 is a logic high level, and the inactive level is a logic low level.

Illustratively, with continued reference to FIG. 40, the pixel circuit 50 includes a drive transistor DT and a switch transistor ST. The switch transistor ST includes a data writing transistor M01, a gate reset transistor M02, a light emission control transistor M03, and an electrode reset transistor M05. The pixel circuit 50 also includes a storage capacitor C01. In an embodiment, the drive transistor DT may have a dual-gate structure, including a top gate and a bottom gate. The top gate is connected to the data writing transistor M01, the gate reset transistor M02, and one plate of the storage capacitor C01. The bottom gate is connected to the other plate of the storage capacitor C01. The gates of the light emission control transistor M03, the data writing transistor M01, the gate reset transistor M02, and the electrode reset transistor M05 may be electrically connected to a light emission control line EM_L, a first scanning line G1_L, a second scanning line G2_L, and a third scanning line G3_L, respectively. The pixel circuit 50 may also be connected to a first power line PV1_L, a first reset line Vref1_L, a second reset line Vref2_L, and a data line Data_L. The drive transistor DT of the pixel circuit 50 may be connected to a first electrode of the light-emitting element OLED. A second electrode of the light-emitting element OLED may be connected to a second power line PV2_L. Coled represents the parasitic capacitance of the light-emitting element OLED.

An example in which all transistors in the pixel circuit 50 are N-type transistors is used. FIG. 41 is a timing graph of the pixel circuit shown in FIG. 40 according to an embodiment of the present disclosure. With reference to FIG. 40 and FIG. 41, during a reset phase t01, both the signal of the second scanning line G2_L and the signal of the third scanning line G3_L include a logic high level, and the gate reset transistor M02 and the electrode reset transistor M05 are turned on. The gate reset transistor M02 may transmit the signal from the first reset line Vref1_L to the gate of the drive transistor DT so that the drive transistor DT is turned on. The electrode reset transistor M05 may transmit the signal from the second reset line Vref2_L to the first electrode of the light-emitting element OLED to clear the residual electrical signal from the previous frame.

During a compensation phase t02, both the signal of the second scanning line G2_L and the signal of the light emission control line EM_L are at a logic high level, and the gate reset transistor M02 and the light emission control transistor M03 are turned on. The gate reset transistor M02 continues to transmit the signal from the first reset line Vref1_L to the gate of the drive transistor DT to control the drive transistor DT to turn on. The light emission control transistor M03 transmits the signal from the first power line PV1_L to the drain of the drive transistor DT and transmits the signal from the first power line PV1_L to the source through the drive transistor DT to perform voltage compensation on the source of the drive transistor DT.

During a data writing phase t03, the signal of the first scanning line G1_L is at a logic high level, and the data writing transistor M01 is turned on. The data writing transistor M01 transmits the signal from the data line Data_L to the gate of the drive transistor DT.

During a light emission phase t04, the signal of the light emission control line EM_L is at a logic high level, and the light emission control transistor M03 is turned on. The light emission control transistor M03 transmits the signal from the first power line PV1_L to the drain of the drive transistor DT and transmits the signal from the first power line PV1_L to the source of the drive transistor DT through the drive transistor DT, that is, to the first electrode of the light-emitting element OLED so that the light-emitting element OLED emits light for display according to the gate potential and the source potential of the drive transistor DT. The second storage capacitor C01 can maintain a stable voltage difference between the gate potential and the source potential of the drive transistor DT.

In an embodiment, the signal output terminal GOUT of the shift register 101 provided by the embodiment of the present disclosure may be connected to the gate of the data writing transistor M01 through the first scanning line G1_L (not shown in FIG. 40). The gate driving signal G1 may control the data writing transistor M01 to turn on or turn off. In another embodiment, the signal output terminal GOUT of the shift register 101 provided by the embodiment of the present disclosure may be connected to the gate of the gate reset transistor M02 through the second scanning line G2_L (not shown in FIG. 40). The gate driving signal G1 may control the gate reset transistor M02 to turn on or turn off. In another embodiment, the signal output terminal GOUT of the shift register 101 provided by the embodiment of the present disclosure may be connected to the gate of the electrode reset transistor M05 through the third scanning line G3_L (not shown in FIG. 40). The gate driving signal G1 may control the electrode reset transistor M05 to turn on or turn off. In other optional embodiments, the shift register 101 provided by the embodiment of the present disclosure may also be electrically connected to both the first scanning line G1_L and the third scanning line G3_L (not shown in FIG. 40) to simultaneously control the data writing transistor M01 and the electrode reset transistor M05 in different pixel circuits 50 to turn on or turn off.

It is to be noted that the preceding description is only an illustrative description of the specific structure and the driving principle of the pixel circuit in the display panel provided by the embodiment of the present disclosure. The structure and the driving principle of the pixel circuit in the embodiment of the present disclosure may be designed according to actual needs, and the embodiment of the present disclosure does not specifically limit the pixel circuit.

On the basis of the preceding embodiments, the shift register 101 includes multiple transistors. The transistors in the shift register 101 are all N-type transistors. The active layers of the switch transistor ST and the transistors in the shift register 101 each include a metal oxide material.

The metal oxide material may include an oxide material of one or more of indium (In), gallium (Ga), tin (Sn), zirconium (Zr), hafnium (Hf), titanium (Ti), and zinc (Zn).

In this manner, when the active layer of the transistor is prepared, it is not required to crystallize to form a crystal structure so that the defect density of the active layer is small. Moreover, the carrier mobility of the active layer is high, and the temperature sensitivity is low so that the voltage stability and switching characteristics of the drive transistor DT are better, and the hysteresis effect and the threshold voltage drift can be further reduced.

In addition, the transistors in the pixel circuit 50 and the transistors in the shift register 101 are all N-type transistors, and the active layers both include a metal oxide material. The transistors in the pixel circuit 50 and the transistors in the shift register 101 may be provided in the same layer, which contributes to reducing the preparation cost.

It can be understood that when the transistors in the pixel circuit 50 and the transistors in the shift register 101 are all N-type transistors, the active levels related to the pixel circuit 50 and the shift register 101 are all logic high levels, and the inactive levels are all logic low levels.

Based on the same inventive concept, an embodiment of the present disclosure also provides a display device. The display device includes the display panel provided by any embodiment of the present disclosure. Therefore, the display device has the technical features of the display panel provided in the embodiment of the present disclosure and can achieve the beneficial effects of the display panel provided in the embodiment of the present disclosure. Similarities may refer to the preceding description of the display panel provided in the embodiment of the present disclosure and are not repeated here.

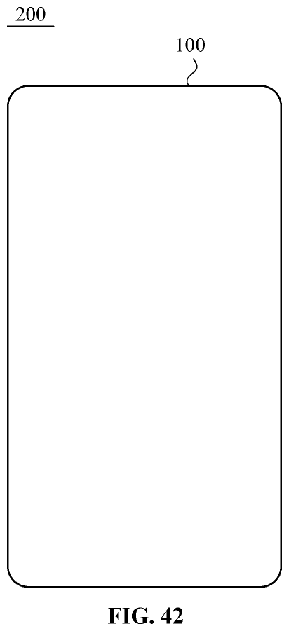

Exemplarily, FIG. 42 is a diagram illustrating the structure of a display device according to an embodiment of the present disclosure. As shown in FIG. 42, the display device 200 includes the display panel 100 provided in embodiments of the present disclosure. The display device 200 provided by the embodiments of the present disclosure may be any electronic product with a display function, including but not limited to the following categories: phones, televisions, laptops, desktop displays, tablet computers, digital cameras, smart bracelets, smart glasses, in-vehicle displays, industry-controlling equipment, medical displays, and touch interactive terminals. No special limitations are made thereto in the embodiments of the present disclosure.

It is to be noted that the preceding description are only preferred embodiments of the present disclosure and the technical principles used therein. It is to be understood by those skilled in the art that the present disclosure is not limited to the embodiments described herein. For those skilled in the art, various apparent modifications, adaptations, combinations, and substitutions can be made without departing from the scope of the present disclosure. Therefore, while the present disclosure is described in detail via the preceding embodiments, the present disclosure is not limited to the preceding embodiments and may include more equivalent embodiments without departing from the concept of the present disclosure. The scope of the present disclosure is determined by the scope of the appended claims.

What is claimed is:

1. A display panel, comprising: a driving circuit, wherein the driving circuit comprises a plurality of shift registers; and
a shift register of the plurality of shift registers comprises a first control circuit, a second control circuit, an isolation control circuit, an output circuit, a signal input terminal, a first clock terminal, a second clock terminal, a first level terminal, a second level terminal, an isolation control terminal, and a signal output terminal;
the first control circuit is electrically connected to the signal input terminal, the first clock terminal, and a first node separately; the isolation control circuit is electrically connected to the isolation control terminal, the first node, and a second node separately; the second control circuit is electrically connected to the first clock terminal, the first level terminal, and a third node separately; and the output circuit is electrically connected to the second node, the third node, the second clock terminal, the second level terminal, and the signal output terminal separately;
wherein in a same shift register, during at least part of a period in which a signal at the second node is at an active level and an input signal at the signal input terminal is at an inactive level, a first clock signal at the first clock terminal controls the first control circuit to disconnect a signal transmission path between the signal input terminal and the first node, and/or an isolation control signal at the isolation control terminal controls the isolation control circuit to disconnect a signal transmission path between the first node and the second node.

2. The display panel according to claim 1, wherein in the same shift register,
during at least part of a period in which the input signal at the signal input terminal is at an active level, the first clock signal at the first clock terminal controls the first control circuit to establish the signal transmission path between the signal input terminal and the first node, and the isolation control signal at the isolation control terminal controls the isolation control circuit to establish the signal transmission path between the first node and the second node.

3. The display panel according to claim 1, wherein in the same shift register,
in a refresh phase of a frame of image, during at least part of a period after a gate driving signal at the signal output terminal transitions from an active level to an inactive level, the first clock signal at the first clock terminal controls the first control circuit to establish the signal transmission path between the signal input terminal and the first node, and the isolation control signal at the isolation control terminal controls the isolation control circuit to establish the signal transmission path between the first node and the second node.

4. The display panel according to claim 1, wherein in the same shift register,
in a refresh phase of a frame of image, during at least part of a period before the input signal at the signal input terminal transitions from an inactive level to an active level, the first clock signal at the first clock terminal controls the first control circuit to establish the signal transmission path between the signal input terminal and the first node, and the isolation control signal at the isolation control terminal controls the isolation control circuit to establish the signal transmission path between the first node and the second node.

5. The display panel according to claim 1, wherein in the same shift register,
a period in which the isolation control signal at the isolation control terminal is at an inactive level overlaps with a period in which the signal at the second node is at an active level; and
a period in which the isolation control signal at the isolation control terminal is at an active level does not overlap with a period in which a gate driving signal at the signal output terminal is at an active level.

6. The display panel according to claim 5, wherein in the same shift register, the isolation control terminal is reused as the third node;
wherein the isolation control circuit comprises an isolation control transistor; and
a first electrode of the isolation control transistor is electrically connected to the first node, a second electrode of the isolation control transistor is electrically connected to the second node, and a gate of the isolation control transistor is electrically connected to the third node.

7. The display panel according to claim 1, wherein the shift register further comprises a third level terminal and a first auxiliary control terminal;
the first control circuit comprises a first input unit and a first auxiliary unit;
a first terminal of the first input unit is electrically connected to the signal input terminal, a second terminal of the first input unit is coupled to the first node, and a control terminal of the first input unit is electrically connected to the first clock terminal; and
a first terminal of the first auxiliary unit is electrically connected to the third level terminal, a second terminal of the first auxiliary unit and the second terminal of the first input unit are electrically connected to a first auxiliary node, and a control terminal of the first auxiliary unit is electrically connected to the first auxiliary control terminal;
wherein in the same shift register, during at least part of the period in which the signal at the second node is at an active level and the input signal at the signal input terminal is at an inactive level, a first auxiliary control signal at the first auxiliary control terminal controls the first auxiliary unit to establish a signal transmission path between the third level terminal and the first auxiliary node.

8. The display panel according to claim 7, wherein in the same shift register,
during a period in which the input signal at the signal input terminal is at an inactive level and the first clock signal at the first clock terminal is at an active level, the first auxiliary control signal at the first auxiliary control terminal controls the first auxiliary unit to disconnect the signal transmission path between the third level terminal and the first auxiliary node; or
the first auxiliary control terminal is reused as the first node, the second node, or the second clock terminal.

9. The display panel according to claim 7, wherein the first control circuit further comprises a second input unit; and
a first terminal of the second input unit and the second terminal of the first input unit are electrically connected to the first auxiliary node, a second terminal of the second input unit is electrically connected to the first node, and a control terminal of the second input unit is electrically connected to the first clock terminal;
wherein the second input unit comprises a second input transistor; and
a first electrode of the second input transistor is electrically connected to the first auxiliary node, a second electrode of the second input transistor is electrically connected to the first node, and a gate of the second input transistor is electrically connected to the first clock terminal.

10. The display panel according to claim 7, wherein the shift register further comprises a first reset circuit;
the first reset circuit comprises a first reset transistor and a second reset transistor; or the first reset circuit comprises a first reset transistor, a second reset transistor, and a third reset transistor;
when the first reset circuit comprises the first reset transistor and the second reset transistor, a first electrode of the first reset transistor is coupled to the first node, a second electrode of the first reset transistor and a first electrode of the second reset transistor are electrically connected to the first auxiliary node, and a gate of the first reset transistor is electrically connected to the second clock terminal; and
a second electrode of the second reset transistor is electrically connected to the second level terminal, and a gate of the second reset transistor is electrically connected to the third node;
when the first reset circuit comprises the first reset transistor, the second reset transistor, and the third reset transistor, the first electrode of the third reset transistor is electrically connected to the first node, the second electrode of the third reset transistor and the first electrode of the first reset transistor are electrically connected to the first auxiliary node, and the gate of the third reset transistor and the gate of the first reset transistor are both electrically connected to the second clock terminal; and
the second electrode of the first reset transistor is electrically connected to the first electrode of the second reset transistor, the second electrode of the second reset transistor is electrically connected to the second level terminal, and the gate of the second reset transistor is electrically connected to the third node.

11. The display panel according to claim 7, wherein the first auxiliary unit comprises a first auxiliary transistor; and
a first electrode of the first auxiliary transistor is electrically connected to the third level terminal, a second electrode of the first auxiliary transistor is electrically connected to the first auxiliary node, and a gate of the first auxiliary transistor is electrically connected to the first auxiliary control terminal;
wherein the third level terminal is reused as the first level terminal, and the first auxiliary control terminal is reused as the first node.

12. The display panel according to claim 1, wherein the shift register further comprises a first reset circuit and a fourth level terminal;
the first reset circuit comprises a first reset transistor, a second reset transistor, and a second auxiliary transistor;
a first electrode of the first reset transistor is electrically connected to the first node, a second electrode of the first reset transistor and a first electrode of the second reset transistor are electrically connected to a second auxiliary node, and a gate of the first reset transistor is electrically connected to the second clock terminal;
a second electrode of the second reset transistor is electrically connected to the second level terminal, and a gate of the second reset transistor is electrically connected to the third node; and
a first electrode of the second auxiliary transistor is electrically connected to the fourth level terminal, a second electrode of the second auxiliary transistor is electrically connected to the second auxiliary node, and a gate of the second auxiliary transistor is electrically connected to the first node or the second node.

13. The display panel according to claim 1, wherein the shift register further comprises a first reset circuit and a fourth level terminal;
the first reset circuit comprises a first reset transistor, a second reset transistor, a third reset transistor, and a second auxiliary transistor;
a first electrode of the third reset transistor is electrically connected to the first node, a second electrode of the third reset transistor and a first electrode of the first reset transistor are electrically connected to a second auxiliary node, and a gate of the third reset transistor and a gate of the first reset transistor are both electrically connected to the second clock terminal;
a second electrode of the first reset transistor is electrically connected to a first electrode of the second reset transistor, a second electrode of the second reset transistor is electrically connected to the second level terminal, and a gate of the second reset transistor is electrically connected to the third node; and
a first electrode of the second auxiliary transistor is electrically connected to the fourth level terminal, a second electrode of the second auxiliary transistor is electrically connected to the second auxiliary node, and a gate of the second auxiliary transistor is electrically connected to the first node or the second node.

14. The display panel according to claim 1, wherein the shift register further comprises a second reset circuit, a fifth level terminal, and a third auxiliary control terminal;
the second reset circuit comprises a fourth reset transistor and a third auxiliary transistor;
a first electrode of the fourth reset transistor is electrically connected to the first clock terminal, a second electrode of the fourth reset transistor is coupled to the third node, and a gate of the fourth reset transistor is electrically connected to the first node; and
a first electrode of the third auxiliary transistor is electrically connected to the fifth level terminal, a second electrode of the third auxiliary transistor and the second electrode of the fourth reset transistor are electrically connected to a third auxiliary node, and a gate of the third auxiliary transistor is electrically connected to the third auxiliary control terminal;
wherein in the same shift register, during at least part of a period in which a gate driving signal at the signal output terminal is at an inactive level, a third auxiliary control signal at the third auxiliary control terminal controls the third auxiliary transistor to establish a signal transmission path between the fifth level terminal and the third auxiliary node.

15. The display panel according to claim 14, wherein in the same shift register, when the gate driving signal at the signal output terminal is at an active level, the third auxiliary control signal at the third auxiliary control terminal controls the third auxiliary transistor to disconnect the signal transmission path between the fifth level terminal and the third auxiliary node; or
wherein the third auxiliary control terminal is reused as the third node.

16. The display panel according to claim 14, wherein
the second reset circuit further comprises a fifth reset transistor; and
a first electrode of the fifth reset transistor and the second electrode of the fourth reset transistor are electrically connected to the third auxiliary node, a second electrode of the fifth reset transistor is electrically connected to the third node, and a gate of the fifth reset transistor is electrically connected to the first node; or
wherein the fifth level terminal is reused as the first level terminal.

17. The display panel according to claim 1, wherein the shift register further comprises a first storage circuit, and the first storage circuit comprises a first storage capacitor; and
a first plate of the first storage capacitor is electrically connected to the first node, and a second plate of the first storage capacitor is electrically connected to a fixed level terminal.

18. The display panel according to claim 1, wherein the first control circuit comprises a first input unit, and the first input unit comprises a first input transistor; and
a first electrode of the first input transistor is electrically connected to the signal input terminal, a second electrode of the first input transistor is coupled to the first node, and a gate of the first input transistor is electrically connected to the first clock terminal.

19. The display panel according to claim 1, wherein
the output circuit comprises a first output transistor and a second output transistor; and
in the same shift register:
a first electrode of the first output transistor is electrically connected to the second clock terminal, a second electrode of the first output transistor is electrically connected to the signal output terminal, and a gate of the first output transistor is electrically connected to the second node; and
a first electrode of the second output transistor is electrically connected to the second level terminal, a second electrode of the second output transistor is electrically connected to the signal output terminal, and a gate of the second output transistor is electrically connected to the third node;
wherein the shift register further comprises a bootstrap circuit, and the bootstrap circuit comprises a bootstrap capacitor; and
a first plate of the bootstrap capacitor is electrically connected to the signal output terminal, and a second plate of the bootstrap capacitor is electrically connected to the second node.

20. A display device, comprising a display panel, wherein the display panel comprises:
a driving circuit, wherein the driving circuit comprises a plurality of shift registers; and
a shift register of the plurality of shift registers comprises a first control circuit, a second control circuit, an isolation control circuit, an output circuit, a signal input terminal, a first clock terminal, a second clock terminal, a first level terminal, a second level terminal, an isolation control terminal, and a signal output terminal;
the first control circuit is electrically connected to the signal input terminal, the first clock terminal, and a first node separately; the isolation control circuit is electrically connected to the isolation control terminal, the first node, and a second node separately; the second control circuit is electrically connected to the first clock terminal, the first level terminal, and a third node separately; and the output circuit is electrically connected to the second node, the third node, the second clock terminal, the second level terminal, and the signal output terminal separately;
wherein in a same shift register, during at least part of a period in which a signal at the second node is at an active level and an input signal at the signal input terminal is at an inactive level, a first clock signal at the first clock terminal controls the first control circuit to disconnect a signal transmission path between the signal input terminal and the first node, and/or an isolation control signal at the isolation control terminal controls the isolation control circuit to disconnect a signal transmission path between the first node and the second node.
